(19) United States
(12) Patent Application Publication
(10) Pub. No.: US 2024/0030674 A1
(43) Pub. Date: Jan. 25, 2024

(54) NANOSECOND PULSED WAVELENGTH AGILE LASER

(71) Applicant: Luminar, LLC, Orlando, FL (US)

(72) Inventor: Alex M. Sincore, Orlando, FL (US)

(21) Appl. No.: 17/871,230

(22) Filed: Jul. 22, 2022

(51) Int. Cl. H01S 3/10; H01S 3/0941; H01S 3/094; G01S 7/481; G01S 7/4865; G01S 7/484; H01S 3/091

(52) U.S. Cl. CPC H01S 3/1001; H01S 3/09415; H01S 3/094096; H01S 3/094076; G01S 7/4814; G01S 7/4865; G01S 7/484; H01S 3/0912; G02B 26/101

(57) ABSTRACT

A system comprises a wavelength-tunable light source and a controller. The controller is configured to cause attenuation of a light being generated by the wavelength-tunable light source during a transition period between a first wavelength to a second wavelength, cause the wavelength-tunable light source to change a wavelength of the light being generated by the wavelength-tunable light source from the first wavelength to the second wavelength, and allow a pulse of the light associated with the second wavelength to be emitted during a pulse period after the transition period.

### BACKGROUND OF THE INVENTION

Light detection and ranging (lidar) is a technology that can be used to measure distances to remote targets. Typically, a lidar system includes a light source and an optical receiver. The light source can include, for example, a laser which emits a light pulse having a particular operating wavelength. The operating wavelength of a light pulse emitted by a lidar system may lie, for example, in the infrared, visible, or ultraviolet portions of the electromagnetic spectrum. The light source emits light towards a target which scatters the light, and some of the scattered light is received back at the receiver. The system determines the distance to the target based on one or more characteristics associated with the received light. For example, the lidar system may determine the distance to the target based on the time of flight for a pulse of light emitted by the light source to travel to the target and back to the lidar system.

### BRIEF DESCRIPTION OF THE DRAWINGS

Various embodiments of the invention are disclosed in the following detailed description and the accompanying drawings.

FIG. 1 illustrates an example light detection and ranging (lidar) system.

FIG. 2 illustrates an example scan pattern produced by a lidar system.

FIG. 3 illustrates an example lidar system with an example rotating polygon mirror.

FIG. 4 illustrates an example light-source field of view (FOVL) and receiver field of view (FOVR) for a lidar system.

FIG. 5 illustrates an example unidirectional scan pattern that includes multiple pixels and multiple scan lines.

FIG. 6 illustrates an example receiver that includes a detector, amplifier, and pulse-detection circuit.

FIG. 7 illustrates an example receiver and an example voltage signal corresponding to a received pulse of light.

FIG. 8 illustrates an example light source that includes a seed laser diode and a semiconductor optical amplifier (SOA).

FIG. 9 illustrates an example light source that includes a semiconductor optical amplifier (SOA) with a tapered optical waveguide.

FIG. 10 is a flow chart illustrating an embodiment of a process of a multi-wavelength lidar system for detecting objects.

FIG. 11 is a flow chart illustrating an embodiment of a process for emitting multi-wavelength light pulses using a wavelength-tunable laser.

FIG. 12 is a flow chart illustrating an embodiment of a process for emitting a light pulse at a new wavelength using a single wavelength-tunable laser.

FIG. 13 is a diagram illustrating graphs depicting example operating conditions of a light source when generating light pulses of different wavelengths using a wavelength-tunable laser.

FIG. 14 illustrates an example computer system.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

A nanosecond wavelength-tunable laser is disclosed. In various embodiments, a configurable laser is a light emitting device capable of rapidly switching between and emitting light pulses of different wavelengths with high wavelength accuracy is disclosed. The nanosecond pulsed wavelength agile laser can be implemented using a grating-coupled laser diode, such as a sampled-grating distributed Bragg reflector (SG-DBR) laser, and is capable of fast wavelength agility (measured in nanoseconds) and can generate nanosecond pulses with very high temporal contrast between pulses. The disclosed light source is particularly applicable for lidar systems that utilize variable wavelength output for scanning.

In various embodiments, the disclosed laser is a laser device component integrated with a semiconductor optical amplifier (SOA). A controller unit synchronizes and modulates a control signal to the SOA to attenuate the output of the laser. For example, the SOA can be modulated between a reverse and forward bias to generate nanosecond pulses with high temporal extinction. In various embodiments, the laser includes at least a front mirror, a back mirror, a phase component, and a gain component. The front mirror section, back mirror section, and/or phase components can be used to switch the laser to a different wavelength. In some embodiments, the gain region is constantly applied with a DC current to maintain the laser in an always on operating mode, allowing the laser to be rapidly switched between different wavelengths. For example, the laser is maintained in an always on operating mode between transmitted light pulses. To generate high contrast nanosecond output pulses, the current applied to the SOA is modulated between reverse and forward biases. A forward bias allows the laser to emit an output light while applying a reverse bias will attenuate the output light. In some embodiments, a monitoring module such as an etalon is used to monitor the current wavelength of the laser. During a wavelength transition phase, a reverse bias is applied to the SOA to attenuate the output light from the laser. When the desired wavelength as monitored is reached, a forward bias followed by a reverse bias is applied to the SOA to emit a light pulse. In some embodiments, the monitoring module is not required, and the wavelength transition period can be approximated by a configured transition time period to allow the wavelength of the laser to stabilize at the desired wavelength before a pulse is emitted.

In some embodiments, a system such as a lidar system includes a wavelength-tunable light source and a controller. For example, a wavelength-tunable light source can be implemented using a seed laser such as a sampled-grating distributed Bragg reflector (SG-DBR) laser that can be configured to rapidly switch between different wavelengths. In various embodiments, the seed laser is a grating-coupled laser diode where current injection modifies the cavity resonance, and a SG-DBR laser is but one example of a seed laser that meets these requirements. The wavelength-tunable light source can be configured by a controller that is communicatively connected to the light source. For example, a controller can be utilized to change the wavelength configuration of the light source and to control the timing of light pulses emitted using the light source. In some embodiments, the controller is configured to cause attenuation of a light being generated by the wavelength-tunable light source during a transition period between a first wavelength to a second wavelength. For example, the controller can be used to disable the light source from emitting light while the light source is being reconfigured to transition from a first wavelength to a second wavelength. In some embodiments, the controller is further configured to cause the wavelength-tunable light source to change a wavelength of the light being generated by the wavelength-tunable light source from the first wavelength to the second wavelength and to allow a pulse of the light associated with the second wavelength to be emitted during a pulse period after the transition period. For example, the controller can configure the light source to generate a light pulse at a different wavelength, including transitioning or alternating between different wavelengths, such as between 1530 nm and 1550 nm. Once the light source has been reconfigured for a different wavelength, the controller can be used to allow the light source to emit a light pulse. In some embodiments, the transition period between different wavelengths is required to allow the laser to be reconfigured for a new wavelength. In some embodiments, during the transition period, the wavelength of the light generated by the laser has not yet stabilized at the desired wavelength. In some embodiments, the wavelength of the light generated by the laser can be monitored, for example, by using an etalon or another measuring device, to determine when the transition period is over. In some embodiments, the transition period is approximated by a configurable time period that allows the laser sufficient time to transition to the new wavelength.

A lidar system operates in a vehicle and includes multiple “eyes,” each of which has its own field of regard, or an angular range over which the eye scans targets using pulses of light in accordance with a scan pattern. The fields of regard can combine along a certain dimension (e.g., horizontally) to define the overall field of regard of the lidar system. The lidar system then can use data received via both eyes to generate a point cloud or otherwise process the received data.

In a two-eye configuration of the lidar system, the two eyes can be housed together and scan the respective fields of regard via a shared window or separate windows, or the eyes can be housed separately. In the latter case, an assembly referred to as a “sensor head” can include a scanner, a receiver, and an optical element such as a collimator or a laser diode to generate or convey a beam of light.

Depending on the implementation, each eye of a lidar system can include a separate scanner (e.g., each eye can be equipped with a pivotable scan mirror to scan the field of regard vertically and another pivotable scan mirror to scan the field of regard horizontally), a partially shared scanner (e.g., each eye can be equipped with a pivotable scan mirror to scan the field of regard vertically, and a shared polygon mirror can scan the corresponding fields of regard horizontally, using different reflective surfaces), or a fully shared scanner (e.g., a pivotable planar mirror can scan the fields of regard vertically by reflecting incident beams at different regions on the reflective surface, and a shared polygon mirror can scan the corresponding fields of regard horizontally, using different reflective surfaces).

Different hardware configurations allow the lidar system to operate the eyes more independently of each other, as is the case with separate scanners, or less independently, as is the case with a fully shared scanner. For example, the two or more eyes may scan the respective fields of regard using similar or different scan patterns. In one implementation, the two eyes trace out the same pattern, but with a certain time differential to maintain angular separation between light-source fields of view and thereby reduce the probability of cross-talk events between the sensor heads. In another implementation, the two eyes scan the corresponding fields of regard according to different scan patterns, at least in some operational states (e.g., when the vehicle is turning right or left).

Further, according to one approach, two eyes of a lidar system are arranged so that the fields of regard of the eyes are adjacent and non-overlapping. For example, each field of regard can span approximately 60 degrees horizontally and 30 degrees vertically, so that the combined field of regard of the lidar system spans approximately 120 degrees horizontally and 30 degrees vertically. The corresponding scanners (or paths within a shared scanner) can point away from each other at a certain angle, for example, so that the respective fields of regard abut approximately at an axis corresponding to the forward-facing direction of the vehicle.

Alternatively, the lidar system can operate in a “cross-eyed” configuration to create an area of overlap between the fields of regard. The area of overlap can be approximately centered along the forward-facing direction or another direction, which in some implementations a controller can determine dynamically. In this implementation, the two sensor heads can yield a higher density of scan in the area that generally is more important. In some implementations, the fields of regard in a cross-eyed two-eye configuration are offset from each other by a half-pixel value, so that the area of overlap has twice as many pixels. In general, the fields of regard can overlap angularly or translationally. To reduce the probability of cross-talk events (e.g., the situation when a pulse emitted by the light source associated with the first eye is received by the receiver of the second eye), the lidar system can use output beams with different wavelengths.

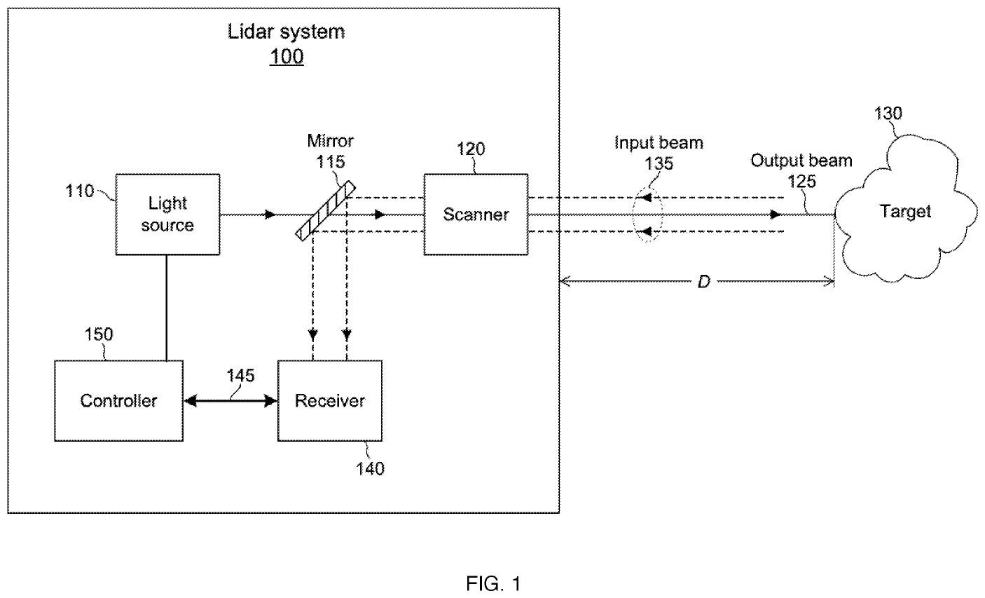

FIG. 1 illustrates an example light detection and ranging (lidar) system 100. In particular embodiments, a lidar system 100 may be referred to as a laser ranging system, a laser radar system, a LIDAR system, a lidar sensor, or a laser detection and ranging (LADAR or ladar) system. In particular embodiments, a lidar system 100 may include a light source 110, mirror 115, scanner 120, receiver 140, or controller 150. The light source 110 may include, for example, a laser which emits light having a particular operating wavelength in the infrared, visible, or ultraviolet portions of the electromagnetic spectrum. As an example, light source 110 may include a laser with one or more operating wavelengths between approximately 900 nanometers (nm) and 2000 nm. The light source 110 emits an output beam of light 125 which may be continuous wave (CW), pulsed, or modulated in any suitable manner for a given application. The output beam of light 125 is directed downrange toward a remote target 130. As an example, the remote target 130 may be located a distance D of approximately 1 m to 1 km from the lidar system 100.

Once the output beam 125 reaches the downrange target 130, the target may scatter or reflect at least a portion of light from the output beam 125, and some of the scattered or reflected light may return toward the lidar system 100. In the example of FIG. 1, the scattered or reflected light is represented by input beam 135, which passes through scanner 120 and is reflected by mirror 115 and directed to receiver 140. In particular embodiments, a relatively small fraction of the light from output beam 125 may return to the lidar system 100 as input beam 135. As an example, the ratio of input beam 135 average power, peak power, or pulse energy to output beam 125 average power, peak power, or pulse energy may be approximately 10⁻¹, 10⁻², 10⁻³, 10⁻⁴, 10⁻⁵, 10⁻⁶, 10⁻⁷, 10⁻⁸, 10⁻⁹, 10⁻¹⁰, 10⁻¹¹, or 10⁻¹². As another example, if a pulse of output beam 125 has a pulse energy of 1 microjoule (μJ), then the pulse energy of a corresponding pulse of input beam 135 may have a pulse energy of approximately 10 nanojoules (nJ), 1 nJ, 100 picojoules (pJ), 10 pJ, 1 pJ, 100 femtojoules (fJ), 10 fJ, 1 fJ, 100 attojoules (aJ), aJ, 1 aJ, or 0.1 aJ.

In particular embodiments, output beam 125 may include or may be referred to as an optical signal, output optical signal, emitted optical signal, output light, emitted pulse of light, laser beam, light beam, optical beam, emitted beam, emitted light, or beam. In particular embodiments, input beam 135 may include or may be referred to as a received optical signal, received pulse of light, input pulse of light, input optical signal, return beam, received beam, return light, received light, input light, scattered light, or reflected light. As used herein, scattered light may refer to light that is scattered or reflected by a target 130. As an example, an input beam 135 may include: light from the output beam 125 that is scattered by target 130; light from the output beam 125 that is reflected by target 130; or a combination of scattered and reflected light from target 130.

In particular embodiments, receiver 140 may receive or detect photons from input beam 135 and produce one or more representative signals. For example, the receiver 140 may produce an output electrical signal 145 that is representative of the input beam 135, and the electrical signal 145 may be sent to controller 150. In particular embodiments, receiver 140 or controller 150 may include a processor, computing system (e.g., an ASIC or FPGA), or other suitable circuitry. A controller 150 may be configured to analyze one or more characteristics of the electrical signal 145 from the receiver 140 to determine one or more characteristics of the target 130, such as its distance downrange from the lidar system 100. This may be done, for example, by analyzing a time of flight or a frequency or phase of a transmitted beam of light 125 or a received beam of light 135. If lidar system 100 measures a time of flight of T (e.g., T represents a round-trip time of flight for an emitted pulse of light to travel from the lidar system 100 to the target 130 and back to the lidar system 100), then the distance D from the target 130 to the lidar system 100 may be expressed as D=c·T/2, where c is the speed of light (approximately 3.0×10⁸ m/s). As an example, if a time of flight is measured to be T=300 ns, then the distance from the target 130 to the lidar system 100 may be determined to be approximately D=45.0 m. As another example, if a time of flight is measured to be T=1.33 μs, then the distance from the target 130 to the lidar system 100 may be determined to be approximately D=199.5 m. In particular embodiments, a distance D from lidar system 100 to a target 130 may be referred to as a distance, depth, or range of target 130. As used herein, the speed of light c refers to the speed of light in any suitable medium, such as for example in air, water, or vacuum. As an example, the speed of light in vacuum is approximately 2.9979×10⁸ m/s, and the speed of light in air (which has a refractive index of approximately 1.0003) is approximately 2.9970×10⁸ m/s.

In particular embodiments, light source 110 may include a pulsed or CW laser. As an example, light source 110 may be a pulsed laser configured to produce or emit pulses of light with a pulse duration or pulse width of approximately 10 picoseconds (ps) to 100 nanoseconds (ns). The pulses may have a pulse duration of approximately 100 ps, 200 ps, 400 ps, 1 ns, 2 ns, 5 ns, 10 ns, 20 ns, 50 ns, 100 ns, or any other suitable pulse duration. As another example, light source 110 may be a pulsed laser that produces pulses with a pulse duration of approximately 1-5 ns. As another example, light source 110 may be a pulsed laser that produces pulses at a pulse repetition frequency of approximately 100 kHz to 10 MHz or a pulse period (e.g., a time between consecutive pulses) of approximately 100 ns to 10 μs. In particular embodiments, light source 110 may have a substantially constant pulse repetition frequency, or light source 110 may have a variable or adjustable pulse repetition frequency. As an example, light source 110 may be a pulsed laser that produces pulses at a substantially constant pulse repetition frequency of approximately 640 kHz (e.g., 640,000 pulses per second), corresponding to a pulse period of approximately 1.56 μs. As another example, light source 110 may have a pulse repetition frequency (which may be referred to as a repetition rate) that can be varied from approximately 200 kHz to 3 MHz. As used herein, a pulse of light may be referred to as an optical pulse, a light pulse, or a pulse.

In some embodiments, light source 110 may emit pulses at different wavelengths and with a particular encoding time delay between the pulses of different wavelengths. For example, two different groups of pulses can each include pulses of different wavelengths and each pulse group can utilize a different encoding time delay. In various embodiments, light source 110 includes at least a single laser capable of emitting light pulses of different wavelengths.

In particular embodiments, light source 110 may include a pulsed or CW laser that produces a free-space output beam 125 having any suitable average optical power. As an example, output beam 125 may have an average power of approximately 1 milliwatt (mW), 10 mW, 100 mW, 1 watt (W), 10 W, or any other suitable average power. In particular embodiments, output beam 125 may include optical pulses with any suitable pulse energy or peak optical power. As an example, output beam 125 may include pulses with a pulse energy of approximately 0.01 μJ, 0.1 μJ, 0.5 μJ, 1 μJ, 2 μJ, 10 μJ, 100 μJ, 1 mJ, or any other suitable pulse energy. As another example, output beam 125 may include pulses with a peak power of approximately 10 W, 100 W, 1 kW, 5 kW, 10 kW, or any other suitable peak power. The peak power (Pₚₑₐₖ) of a pulse of light can be related to the pulse energy (E) by the expression E=Pₚₑₐₖ·Δt, where Δt is the duration of the pulse, and the duration of a pulse may be defined as the full width at half maximum duration of the pulse. For example, an optical pulse with a duration of 1 ns and a pulse energy of 1 μJ has a peak power of approximately 1 kW. The average power (Pₐᵥ) of an output beam 125 can be related to the pulse repetition frequency (PRF) and pulse energy by the expression Pₐᵥ=PRF·E. For example, if the pulse repetition frequency is 500 kHz, then the average power of an output beam 125 with 1-μJ pulses is approximately 0.5 W.

In particular embodiments, light source 110 may include a laser diode, such as for example, a Fabry-Perot laser diode, a quantum well laser, a distributed Bragg reflector (DBR) laser, a distributed feedback (DFB) laser, a vertical-cavity surface-emitting laser (VCSEL), a quantum dot laser diode, a grating-coupled surface-emitting laser (GCSEL), a slab-coupled optical waveguide laser (SCOWL), a single-transverse-mode laser diode, a multi-mode broad area laser diode, a laser-diode bar, a laser-diode stack, or a tapered-stripe laser diode. As an example, light source 110 may include an aluminum-gallium-arsenide (AlGaAs) laser diode, an indium-gallium-arsenide (InGaAs) laser diode, an indium-gallium-arsenide-phosphide (InGaAsP) laser diode, or a laser diode that includes any suitable combination of aluminum (Al), indium (In), gallium (Ga), arsenic (As), phosphorous (P), or any other suitable material. In particular embodiments, light source 110 may include a pulsed or CW laser diode with a peak emission wavelength between 1200 nm and 1600 nm. As an example, light source 110 may include a current-modulated InGaAsP DFB laser diode that produces optical pulses at a wavelength of approximately 1550 nm. As another example, light source 110 may include a laser diode that emits light at a wavelength between 1500 nm and 1510 nm.

In particular embodiments, light source 110 may include a pulsed or CW laser diode followed by one or more optical-amplification stages. For example, a seed laser diode may produce a seed optical signal, and an optical amplifier may amplify the seed optical signal to produce an amplified optical signal that is emitted by the light source 110. In particular embodiments, an optical amplifier may include a fiber-optic amplifier or a semiconductor optical amplifier (SOA). For example, a pulsed laser diode may produce relatively low-power optical seed pulses which are amplified by a fiber-optic amplifier. As another example, a light source 110 may include a fiber-laser module that includes a current-modulated laser diode with an operating wavelength of approximately 1550 nm followed by a single-stage or a multi-stage erbium-doped fiber amplifier (EDFA) or erbium-ytterbium-doped fiber amplifier (EYDFA) that amplifies the seed pulses from the laser diode. As another example, light source 110 may include a continuous-wave (CW) or quasi-CW laser diode followed by an external optical modulator (e.g., an electro-optic amplitude modulator). The optical modulator may modulate the CW light from the laser diode to produce optical pulses which are sent to a fiber-optic amplifier or SOA. As another example, light source 110 may include a pulsed or CW seed laser diode followed by a semiconductor optical amplifier (SOA). The SOA may include an active optical waveguide configured to receive light from the seed laser diode and amplify the light as it propagates through the waveguide. The optical gain of the SOA may be provided by pulsed or direct-current (DC) electrical current supplied to the SOA. The SOA may be integrated on the same chip as the seed laser diode, or the SOA may be a separate device with an anti-reflection coating on its input facet or output facet. As another example, light source 110 may include a seed laser diode followed by an SOA, which in turn is followed by a fiber-optic amplifier. For example, the seed laser diode may produce relatively low-power seed pulses which are amplified by the SOA, and the fiber-optic amplifier may further amplify the optical pulses. In some embodiments, the SOA is a tapered SOA. For example, the SOA includes at least a tapered structure and is capable of high output powers for the desired wavelengths.

In particular embodiments, light source 110 may include a direct-emitter laser diode. A direct-emitter laser diode (which may be referred to as a direct emitter) may include a laser diode which produces light that is not subsequently amplified by an optical amplifier. A light source 110 that includes a direct-emitter laser diode may not include an optical amplifier, and the output light produced by a direct emitter may not be amplified after it is emitted by the laser diode. The light produced by a direct-emitter laser diode (e.g., optical pulses, CW light, or frequency-modulated light) may be emitted directly as a free-space output beam 125 without being amplified. A direct-emitter laser diode may be driven by an electrical power source that supplies current pulses to the laser diode, and each current pulse may result in the emission of an output optical pulse.

In particular embodiments, light source 110 may include a diode-pumped solid-state (DPSS) laser. A DPSS laser (which may be referred to as a solid-state laser) may refer to a laser that includes a solid-state, glass, ceramic, or crystal-based gain medium that is pumped by one or more pump laser diodes. The gain medium may include a host material that is doped with rare-earth ions (e.g., neodymium, erbium, ytterbium, or praseodymium). For example, a gain medium may include a yttrium aluminum garnet (YAG) crystal that is doped with neodymium (Nd) ions, and the gain medium may be referred to as a Nd:YAG crystal. A DPSS laser with a Nd:YAG gain medium may produce light at a wavelength between approximately 1300 nm and approximately 1400 nm, and the Nd:YAG gain medium may be pumped by one or more pump laser diodes with an operating wavelength between approximately 730 nm and approximately 900 nm. A DPSS laser may be a passively Q-switched laser that includes a saturable absorber (e.g., a vanadium-doped crystal that acts as a saturable absorber). Alternatively, a DPSS laser may be an actively Q-switched laser that includes an active Q-switch (e.g., an acousto-optic modulator or an electro-optic modulator). A passively or actively Q-switched DPSS laser may produce output optical pulses that form an output beam 125 of a lidar system 100.

In particular embodiments, an output beam of light 125 emitted by light source 110 may be a collimated optical beam having any suitable beam divergence, such as for example, a full-angle beam divergence of approximately 0.5 to 10 milliradians (mrad). A divergence of output beam 125 may refer to an angular measure of an increase in beam size (e.g., a beam radius or beam diameter) as output beam 125 travels away from light source 110 or lidar system 100. In particular embodiments, output beam 125 may have a substantially circular cross section with a beam divergence characterized by a single divergence value. As an example, an output beam 125 with a circular cross section and a full-angle beam divergence of 2 mrad may have a beam diameter or spot size of approximately 20 cm at a distance of 100 m from lidar system 100. In particular embodiments, output beam 125 may have a substantially elliptical cross section characterized by two divergence values. As an example, output beam 125 may have a fast axis and a slow axis, where the fast-axis divergence is greater than the slow-axis divergence. As another example, output beam 125 may be an elliptical beam with a fast-axis divergence of 4 mrad and a slow-axis divergence of 2 mrad.

In particular embodiments, an output beam of light 125 emitted by light source 110 may be unpolarized or randomly polarized, may have no specific or fixed polarization (e.g., the polarization may vary with time), or may have a particular polarization (e.g., output beam 125 may be linearly polarized, elliptically polarized, or circularly polarized). As an example, light source 110 may produce light with no specific polarization or may produce light that is linearly polarized.

In particular embodiments, lidar system 100 may include one or more optical components configured to reflect, focus, filter, shape, modify, steer, or direct light within the lidar system 100 or light produced or received by the lidar system 100 (e.g., output beam 125 or input beam 135). As an example, lidar system 100 may include one or more lenses, mirrors, filters (e.g., band-pass or interference filters), beam splitters, optical splitters, polarizers, polarizing beam splitters, wave plates (e.g., half-wave or quarter-wave plates), diffractive elements, holographic elements, isolators, couplers, detectors, beam combiners, or collimators. The optical components in a lidar system 100 may be free-space optical components, fiber-coupled optical components, or a combination of free-space and fiber-coupled optical components.

In particular embodiments, lidar system 100 may include a telescope, one or more lenses, or one or more mirrors configured to expand, focus, or collimate the output beam 125 or the input beam 135 to a desired beam diameter or divergence. As an example, the lidar system 100 may include one or more lenses to focus the input beam 135 onto a photodetector of receiver 140. As another example, the lidar system 100 may include one or more flat mirrors or curved mirrors (e.g., concave, convex, or parabolic mirrors) to steer or focus the output beam 125 or the input beam 135. For example, the lidar system 100 may include an off-axis parabolic mirror to focus the input beam 135 onto a photodetector of receiver 140. As illustrated in FIG. 1, the lidar system 100 may include mirror 115 (which may be a metallic or dielectric mirror), and mirror 115 may be configured so that light beam 125 passes through the mirror 115 or passes along an edge or side of the mirror 115 and input beam 135 is reflected toward the receiver 140. As an example, mirror 115 (which may be referred to as an overlap mirror, superposition mirror, or beam-combiner mirror) may include a hole, slot, or aperture which output light beam 125 passes through. As another example, rather than passing through the mirror 115, the output beam 125 may be directed to pass alongside the mirror 115 with a gap (e.g., a gap of width approximately mm, 0.5 mm, 1 mm, 2 mm, 5 mm, or 10 mm) between the output beam 125 and an edge of the mirror 115.

In particular embodiments, mirror 115 may provide for output beam 125 and input beam 135 to be substantially coaxial so that the two beams travel along approximately the same optical path (albeit in opposite directions). The input and output beams being substantially coaxial may refer to the beams being at least partially overlapped or sharing a common propagation axis so that input beam 135 and output beam 125 travel along substantially the same optical path (albeit in opposite directions). As an example, output beam 125 and input beam 135 may be parallel to each other to within less than 10 mrad, 5 mrad, 2 mrad, 1 mrad, 0.5 mrad, or mrad. As output beam 125 is scanned across a field of regard, the input beam 135 may follow along with the output beam 125 so that the coaxial relationship between the two beams is maintained.

In particular embodiments, lidar system 100 may include a scanner 120 configured to scan an output beam 125 across a field of regard of the lidar system 100. As an example, scanner 120 may include one or more scanning mirrors configured to pivot, rotate, oscillate, or move in an angular manner about one or more rotation axes. The output beam 125 may be reflected by a scanning mirror, and as the scanning mirror pivots or rotates, the reflected output beam 125 may be scanned in a corresponding angular manner. As an example, a scanning mirror may be configured to periodically pivot back and forth over a 30-degree range, which results in the output beam 125 scanning back and forth across a 60-degree range (e.g., a 0-degree rotation by a scanning mirror results in a 20-degree angular scan of output beam 125).

In particular embodiments, a scanning mirror (which may be referred to as a scan mirror) may be attached to or mechanically driven by a scanner actuator or mechanism which pivots or rotates the mirror over a particular angular range (e.g., over a 5° angular range, 30° angular range, 60° angular range, 120° angular range, 360° angular range, or any other suitable angular range). A scanner actuator or mechanism configured to pivot or rotate a mirror may include a galvanometer scanner, a resonant scanner, a piezoelectric actuator, a voice coil motor, an electric motor (e.g., a DC motor, a brushless DC motor, a synchronous electric motor, or a stepper motor), a microelectromechanical systems (MEMS) device, or any other suitable actuator or mechanism. As an example, a scanner 120 may include a scanning mirror attached to a galvanometer scanner configured to pivot back and forth over a 1° to 30° angular range. As another example, a scanner 120 may include a scanning mirror that is attached to or is part of a MEMS device configured to scan over a 1° to 30° angular range. As another example, a scanner 120 may include a polygon mirror configured to rotate continuously in the same direction (e.g., rather than pivoting back and forth, the polygon mirror continuously rotates 360 degrees in a clockwise or counterclockwise direction). The polygon mirror may be coupled or attached to a synchronous motor configured to rotate the polygon mirror at a substantially fixed rotational frequency (e.g., a rotational frequency of approximately 1 Hz, 10 Hz, 50 Hz, 100 Hz, 500 Hz, or 1,000 Hz).

In particular embodiments, scanner 120 may be configured to scan the output beam 125 (which may include at least a portion of the light emitted by light source 110) across a field of regard of the lidar system 100. A field of regard (FOR) of a lidar system 100 may refer to an area, region, or angular range over which the lidar system 100 may be configured to scan or capture distance information. As an example, a lidar system 100 with an output beam 125 with a 30-degree scanning range may be referred to as having a 30-degree angular field of regard. As another example, a lidar system 100 with a scanning mirror that rotates over a 30-degree range may produce an output beam 125 that scans across a 60-degree range (e.g., a 60-degree FOR). In particular embodiments, lidar system 100 may have a FOR of approximately 10°, 20°, 40°, 60°, 120°, 360°, or any other suitable FOR.

In particular embodiments, scanner 120 may be configured to scan the output beam 125 horizontally and vertically, and lidar system 100 may have a particular FOR along the horizontal direction and another particular FOR along the vertical direction. As an example, lidar system 100 may have a horizontal FOR of 10° to 120° and a vertical FOR of 2° to 45°. In particular embodiments, scanner 120 may include a first scan mirror and a second scan mirror, where the first scan mirror directs the output beam 125 toward the second scan mirror, and the second scan mirror directs the output beam 125 downrange from the lidar system 100. As an example, the first scan mirror may scan the output beam 125 along a first direction, and the second scan mirror may scan the output beam 125 along a second direction that is substantially orthogonal to the first direction. As another example, the first scan mirror may scan the output beam 125 along a substantially horizontal direction, and the second scan mirror may scan the output beam 125 along a substantially vertical direction (or vice versa). As another example, the first and second scan mirrors may each be driven by galvanometer scanners. As another example, the first or second scan mirror may include a polygon mirror driven by an electric motor. In particular embodiments, scanner 120 may be referred to as a beam scanner, optical scanner, or laser scanner.

In particular embodiments, one or more scanning mirrors may be communicatively coupled to controller 150 which may control the scanning mirror(s) so as to guide the output beam 125 in a desired direction downrange or along a desired scan pattern. In particular embodiments, a scan pattern may refer to a pattern or path along which the output beam 125 is directed. As an example, scanner 120 may include two scanning mirrors configured to scan the output beam 125 across a 60° horizontal FOR and a 20° vertical FOR. The two scanner mirrors may be controlled to follow a scan path that substantially covers the 60°×20° FOR. As an example, the scan path may result in a point cloud with pixels that substantially cover the 60°×20° FOR. The pixels may be approximately evenly distributed across the 60°×20° FOR. Alternatively, the pixels may have a particular nonuniform distribution (e.g., the pixels may be distributed across all or a portion of the 60°×20° FOR, and the pixels may have a higher density in one or more particular regions of the 60°×20° FOR).

In particular embodiments, a lidar system 100 may include a scanner 120 with a solid-state scanning device. A solid-state scanning device may refer to a scanner 120 that scans an output beam 125 without the use of moving parts (e.g., without the use of a mechanical scanner, such as a mirror that rotates or pivots). For example, a solid-state scanner 120 may include one or more of the following: an optical phased array scanning device; a liquid-crystal scanning device; or a liquid lens scanning device. A solid-state scanner 120 may be an electrically addressable device that scans an output beam 125 along one axis (e.g., horizontally) or along two axes (e.g., horizontally and vertically). In particular embodiments, a scanner 120 may include a solid-state scanner and a mechanical scanner. For example, a scanner 120 may include an optical phased array scanner configured to scan an output beam 125 in one direction and a galvanometer scanner that scans the output beam 125 in an orthogonal direction. The optical phased array scanner may scan the output beam relatively rapidly in a horizontal direction across the field of regard (e.g., at a scan rate of 50 to 1,000 scan lines per second), and the galvanometer may pivot a mirror at a rate of 1-30 Hz to scan the output beam 125 vertically.

In particular embodiments, a lidar system 100 may include a light source 110 configured to emit pulses of light and a scanner 120 configured to scan at least a portion of the emitted pulses of light across a field of regard of the lidar system 100. One or more of the emitted pulses of light may be scattered by a target 130 located downrange from the lidar system 100, and a receiver 140 may detect at least a portion of the pulses of light scattered by the target 130. A receiver 140 may be referred to as a photoreceiver, optical receiver, optical sensor, detector, photodetector, or optical detector. In particular embodiments, lidar system 100 may include a receiver 140 that receives or detects at least a portion of input beam 135 and produces an electrical signal that corresponds to input beam 135. As an example, if input beam 135 includes an optical pulse, then receiver 140 may produce an electrical current or voltage pulse that corresponds to the optical pulse detected by receiver 140. As another example, receiver 140 may include one or more avalanche photodiodes (APDs) or one or more single-photon avalanche diodes (SPADs). As another example, receiver 140 may include one or more PN photodiodes (e.g., a photodiode structure formed by a p-type semiconductor and an n-type semiconductor, where the PN acronym refers to the structure having p-doped and n-doped regions) or one or more PIN photodiodes (e.g., a photodiode structure formed by an undoped intrinsic semiconductor region located between p-type and n-type regions, where the PIN acronym refers to the structure having p-doped, intrinsic, and n-doped regions). An APD, SPAD, PN photodiode, or PIN photodiode may each be referred to as a detector, photodetector, or photodiode. A detector may have an active region or an avalanche-multiplication region that includes silicon, germanium, InGaAs, InAsSb (indium arsenide antimonide), AlAsSb (aluminum arsenide antimonide), or AlInAsSb (aluminum indium arsenide antimonide). The active region may refer to an area over which a detector may receive or detect input light. An active region may have any suitable size or diameter, such as for example, a diameter of approximately 10 μm, 25 μm, 50 μm, 80 μm, 100 μm, 200 μm, 500 μm, 1 mm, 2 mm, or 5 mm.

In particular embodiments, receiver 140 may include electronic circuitry that performs signal amplification, sampling, filtering, signal conditioning, analog-to-digital conversion, time-to-digital conversion, pulse detection, threshold detection, rising-edge detection, or falling-edge detection. As an example, receiver 140 may include a transimpedance amplifier that converts a received photocurrent (e.g., a current produced by an APD in response to a received optical signal) into a voltage signal. The voltage signal may be sent to pulse-detection circuitry that produces an analog or digital output signal 145 that corresponds to one or more optical characteristics (e.g., rising edge, falling edge, amplitude, duration, or energy) of a received optical pulse. As an example, the pulse-detection circuitry may perform a time-to-digital conversion to produce a digital output signal 145. The electrical output signal 145 may be sent to controller 150 for processing or analysis (e.g., to determine a time-of-flight value corresponding to a received optical pulse).

In particular embodiments, a controller 150 (which may include or may be referred to as a processor, an FPGA, an ASIC, a computer, or a computing system) may be located within a lidar system 100 or outside of a lidar system 100. Alternatively, one or more parts of a controller 150 may be located within a lidar system 100, and one or more other parts of a controller 150 may be located outside a lidar system 100. In particular embodiments, one or more parts of a controller 150 may be located within a receiver 140 of a lidar system 100, and one or more other parts of a controller 150 may be located in other parts of the lidar system 100. For example, a receiver 140 may include an FPGA or ASIC configured to process an output electrical signal from the receiver 140, and the processed signal may be sent to a computing system located elsewhere within the lidar system 100 or outside the lidar system 100. In particular embodiments, a controller 150 may include any suitable arrangement or combination of logic circuitry, analog circuitry, or digital circuitry.

In particular embodiments, controller 150 may be electrically coupled or communicatively coupled to light source 110, scanner 120, or receiver 140. As an example, controller 150 may receive electrical trigger pulses or edges from light source 110, where each pulse or edge corresponds to the emission of an optical pulse by light source 110. As another example, controller 150 may provide instructions, a control signal, a trigger signal, and/or other appropriate control signals to light source 110 indicating when light source 110 should produce optical pulses and/or the light source configuration associated with the produced optical pulses such as the desired wavelength of a light pulse. As another example, controller 150 can provide control signals to attenuate, including disabling and/or enabling, the light being generated by and emitted from light source 110. Controller 150 may send an electrical trigger signal that includes electrical pulses, where each electrical pulse results in the emission of an optical pulse by light source 110. In particular embodiments, the frequency, period, duration, pulse energy, peak power, average power, or wavelength of the optical pulses produced by light source 110 may be adjusted based on instructions, a control signal, or trigger pulses provided by controller 150. In particular embodiments, controller 150 may be coupled to light source 110 and receiver 140, and controller 150 may determine a time-of-flight value for an optical pulse based on timing information associated with when the pulse was emitted by light source 110 and when a portion of the pulse (e.g., input beam 135) was detected or received by receiver 140. In particular embodiments, controller 150 may include circuitry that performs signal amplification, sampling, filtering, signal conditioning, analog-to-digital conversion, time-to-digital conversion, pulse detection, threshold detection, rising-edge detection, or falling-edge detection.

In particular embodiments, lidar system 100 may include one or more processors (e.g., a controller 150) configured to determine a distance D from the lidar system 100 to a target 130 based at least in part on a round-trip time of flight for an emitted pulse of light to travel from the lidar system 100 to the target 130 and back to the lidar system 100. The target 130 may be at least partially contained within a field of regard of the lidar system 100 and located a distance D from the lidar system 100 that is less than or equal to an operating range (R_{OP}) of the lidar system 100. In particular embodiments, an operating range (which may be referred to as an operating distance) of a lidar system 100 may refer to a distance over which the lidar system 100 is configured to sense or identify targets 130 located within a field of regard of the lidar system 100. The operating range of lidar system 100 may be any suitable distance, such as for example, 25 m, 50 m, 100 m, 200 m, 250 m, 500 m, or 1 km. As an example, a lidar system 100 with a 200-m operating range may be configured to sense or identify various targets 130 located up to 200 m away from the lidar system 100. The operating range R_{OP} of a lidar system 100 may be related to the time τ between the emission of successive optical signals by the expression R_{OP}=c·τ/2. For a lidar system 100 with a 200-m operating range (R_{OP}=200 m), the time τ between successive pulses (which may be referred to as a pulse period, a pulse repetition interval (PRI), or a time period between pulses) is approximately 2·R_{OP}/c≅1.33 μs. The pulse period τ may also correspond to the time of flight for a pulse to travel to and from a target 130 located a distance R_{OP} from the lidar system 100. Additionally, the pulse period τ may be related to the pulse repetition frequency (PRF) by the expression τ=1/PRF. For example, a pulse period of 1.33 μs corresponds to a PRF of approximately 752 kHz.

In particular embodiments, a lidar system 100 may be used to determine the distance to one or more downrange targets 130. By scanning the lidar system 100 across a field of regard, the system may be used to map the distance to a number of points within the field of regard. Each of these depth-mapped points may be referred to as a pixel or a voxel. A collection of pixels captured in succession (which may be referred to as a depth map, a point cloud, or a frame) may be rendered as an image or may be analyzed to identify or detect objects or to determine a shape or distance of objects within the FOR. As an example, a point cloud may cover a field of regard that extends 60° horizontally and 15° vertically, and the point cloud may include a frame of 100-2000 pixels in the horizontal direction by 4-400 pixels in the vertical direction.

In particular embodiments, lidar system 100 may be configured to repeatedly capture or generate point clouds of a field of regard at any suitable frame rate between approximately 0.1 frames per second (FPS) and approximately 1,000 FPS. As an example, lidar system 100 may generate point clouds at a frame rate of approximately 0.1 FPS, 0.5 FPS, 1 FPS, 2 FPS, 5 FPS, 10 FPS, 20 FPS, 100 FPS, 500 FPS, or 1,000 FPS. As another example, lidar system 100 may be configured to produce optical pulses at a rate of 5×10⁵ pulses/second (e.g., the system may determine 500,000 pixel distances per second) and scan a frame of 1000×50 pixels (e.g., 50,000 pixels/frame), which corresponds to a point-cloud frame rate of 10 frames per second (e.g., 10 point clouds per second). In particular embodiments, a point-cloud frame rate may be substantially fixed, or a point-cloud frame rate may be dynamically adjustable. As an example, a lidar system 100 may capture one or more point clouds at a particular frame rate (e.g., 1 Hz) and then switch to capture one or more point clouds at a different frame rate (e.g., 10 Hz). A slower frame rate (e.g., 1 Hz) may be used to capture one or more high-resolution point clouds, and a faster frame rate (e.g., 10 Hz) may be used to rapidly capture multiple lower-resolution point clouds.

In particular embodiments, a lidar system 100 may be configured to sense, identify, or determine distances to one or more targets 130 within a field of regard. As an example, a lidar system 100 may determine a distance to a target 130, where all or part of the target 130 is contained within a field of regard of the lidar system 100. All or part of a target 130 being contained within a FOR of the lidar system 100 may refer to the FOR overlapping, encompassing, or enclosing at least a portion of the target 130. In particular embodiments, target 130 may include all or part of an object that is moving or stationary relative to lidar system 100. As an example, target 130 may include all or a portion of a person, vehicle, motorcycle, truck, train, bicycle, wheelchair, pedestrian, animal, road sign, traffic light, lane marking, road-surface marking, parking space, pylon, guard rail, traffic barrier, pothole, railroad crossing, obstacle in or near a road, curb, stopped vehicle on or beside a road, utility pole, house, building, trash can, mailbox, tree, any other suitable object, or any suitable combination of all or part of two or more objects. In particular embodiments, a target may be referred to as an object.

In particular embodiments, light source 110, scanner 120, and receiver 140 may be packaged together within a single housing, where a housing may refer to a box, case, or enclosure that holds or contains all or part of a lidar system 100. As an example, a lidar-system enclosure may contain a light source 110, mirror 115, scanner 120, and receiver 140 of a lidar system 100. Additionally, the lidar-system enclosure may include a controller 150. The lidar-system enclosure may also include one or more electrical connections for conveying electrical power or electrical signals to or from the enclosure. In particular embodiments, one or more components of a lidar system 100 may be located remotely from a lidar-system enclosure. As an example, all or part of light source 110 may be located remotely from a lidar-system enclosure, and pulses of light produced by the light source 110 may be conveyed to the enclosure via optical fiber. As another example, all or part of a controller 150 may be located remotely from a lidar-system enclosure.

In particular embodiments, light source 110 may include an eye-safe laser, or lidar system 100 may be classified as an eye-safe laser system or laser product. An eye-safe laser, laser system, or laser product may refer to a system that includes a laser with an emission wavelength, average power, peak power, peak intensity, pulse energy, beam size, beam divergence, exposure time, or scanned output beam such that emitted light from the system presents little or no possibility of causing damage to a person's eyes. As an example, light source 110 or lidar system 100 may be classified as a Class 1 laser product (as specified by the 60825-1:2014 standard of the International Electrotechnical Commission (IEC)) or a Class I laser product (as specified by Title 21, Section 1040.10 of the United States Code of Federal Regulations (CFR)) that is safe under all conditions of normal use. In particular embodiments, lidar system 100 may be an eye-safe laser product (e.g., with a Class 1 or Class I classification) configured to operate at any suitable wavelength between approximately 900 nm and approximately 2100 nm. As an example, lidar system 100 may include a laser with an operating wavelength between approximately 1200 nm and approximately 1400 nm or between approximately 1400 nm and approximately 1600 nm, and the laser or the lidar system 100 may be operated in an eye-safe manner. As another example, lidar system 100 may be an eye-safe laser product that includes a scanned laser with an operating wavelength between approximately 900 nm and approximately 1700 nm. As another example, lidar system 100 may be a Class 1 or Class I laser product that includes a laser diode, fiber laser, or solid-state laser with an operating wavelength between approximately 1200 nm and approximately 1600 nm. As another example, lidar system 100 may have operating wavelengths between approximately 1500 nm and approximately 1550 nm.

In particular embodiments, one or more lidar systems 100 may be integrated into a vehicle. As an example, multiple lidar systems 100 may be integrated into a car to provide a complete 360-degree horizontal FOR around the car. As another example, 2-10 lidar systems 100, each system having a 45-degree to 180-degree horizontal FOR, may be combined together to form a sensing system that provides a point cloud covering a 360-degree horizontal FOR. The lidar systems 100 may be oriented so that adjacent FORs have an amount of spatial or angular overlap to allow data from the multiple lidar systems 100 to be combined or stitched together to form a single or continuous 360-degree point cloud. As an example, the FOR of each lidar system 100 may have approximately 1-30 degrees of overlap with an adjacent FOR. In particular embodiments, a vehicle may refer to a mobile machine configured to transport people or cargo. For example, a vehicle may include, may take the form of, or may be referred to as a car, automobile, motor vehicle, truck, bus, van, trailer, off-road vehicle, farm vehicle, lawn mower, construction equipment, forklift, robot, golf cart, motorhome, taxi, motorcycle, scooter, bicycle, skateboard, train, snowmobile, watercraft (e.g., a ship or boat), aircraft (e.g., a fixed-wing aircraft, helicopter, or dirigible), unmanned aerial vehicle (e.g., drone), or spacecraft. In particular embodiments, a vehicle may include an internal combustion engine or an electric motor that provides propulsion for the vehicle.

In particular embodiments, one or more lidar systems 100 may be included in a vehicle as part of an advanced driver assistance system (ADAS) to assist a driver of the vehicle in operating the vehicle. For example, a lidar system 100 may be part of an ADAS that provides information (e.g., about the surrounding environment) or feedback to a driver (e.g., to alert the driver to potential problems or hazards) or that automatically takes control of part of a vehicle (e.g., a braking system or a steering system) to avoid collisions or accidents. A lidar system 100 may be part of a vehicle ADAS that provides adaptive cruise control, automated braking, automated parking, collision avoidance, alerts the driver to hazards or other vehicles, maintains the vehicle in the correct lane, or provides a warning if an object or another vehicle is in a blind spot.

In particular embodiments, one or more lidar systems 100 may be integrated into a vehicle as part of an autonomous-vehicle driving system. As an example, a lidar system 100 may provide information about the surrounding environment to a driving system of an autonomous vehicle. An autonomous-vehicle driving system may be configured to guide the autonomous vehicle through an environment surrounding the vehicle and toward a destination. An autonomous-vehicle driving system may include one or more computing systems that receive information from a lidar system 100 about the surrounding environment, analyze the received information, and provide control signals to the vehicle's driving systems (e.g., steering mechanism, accelerator, brakes, lights, or turn signals). As an example, a lidar system 100 integrated into an autonomous vehicle may provide an autonomous-vehicle driving system with a point cloud every 0.1 seconds (e.g., the point cloud has a 10 Hz update rate, representing 10 frames per second). The autonomous-vehicle driving system may analyze the received point clouds to sense or identify targets 130 and their respective locations, distances, or speeds, and the autonomous-vehicle driving system may update control signals based on this information. As an example, if lidar system 100 detects a vehicle ahead that is slowing down or stopping, the autonomous-vehicle driving system may send instructions to release the accelerator and apply the brakes.

In particular embodiments, an autonomous vehicle may be referred to as an autonomous car, driverless car, self-driving car, robotic car, or unmanned vehicle. In particular embodiments, an autonomous vehicle may refer to a vehicle configured to sense its environment and navigate or drive with little or no human input. As an example, an autonomous vehicle may be configured to drive to any suitable location and control or perform all safety-critical functions (e.g., driving, steering, braking, parking) for the entire trip, with the driver not expected to control the vehicle at any time. As another example, an autonomous vehicle may allow a driver to safely turn their attention away from driving tasks in particular environments (e.g., on freeways), or an autonomous vehicle may provide control of a vehicle in all but a few environments, requiring little or no input or attention from the driver.

In particular embodiments, an autonomous vehicle may be configured to drive with a driver present in the vehicle, or an autonomous vehicle may be configured to operate the vehicle with no driver present. As an example, an autonomous vehicle may include a driver's seat with associated controls (e.g., steering wheel, accelerator pedal, and brake pedal), and the vehicle may be configured to drive with no one seated in the driver's seat or with little or no input from a person seated in the driver's seat. As another example, an autonomous vehicle may not include any driver's seat or associated driver's controls, and the vehicle may perform substantially all driving functions (e.g., driving, steering, braking, parking, and navigating) without human input. As another example, an autonomous vehicle may be configured to operate without a driver (e.g., the vehicle may be configured to transport human passengers or cargo without a driver present in the vehicle). As another example, an autonomous vehicle may be configured to operate without any human passengers (e.g., the vehicle may be configured for transportation of cargo without having any human passengers onboard the vehicle).

In particular embodiments, an optical signal (which may be referred to as a light signal, a light waveform, an optical waveform, an output beam, an emitted optical signal, or emitted light) may include pulses of light, CW light, amplitude-modulated light, frequency-modulated (FM) light, or any suitable combination thereof. Although this disclosure describes or illustrates example embodiments of lidar systems 100 or light sources 110 that produce optical signals that include pulses of light, the embodiments described or illustrated herein may also be applied, where appropriate, to other types of optical signals, including continuous-wave (CW) light, amplitude-modulated optical signals, or frequency-modulated optical signals. For example, a lidar system 100 as described or illustrated herein may be a pulsed lidar system and may include a light source 110 that produces pulses of light. Alternatively, a lidar system 100 may be configured to operate as a frequency-modulated continuous-wave (FMCW) lidar system and may include a light source 110 that produces CW light or a frequency-modulated optical signal.

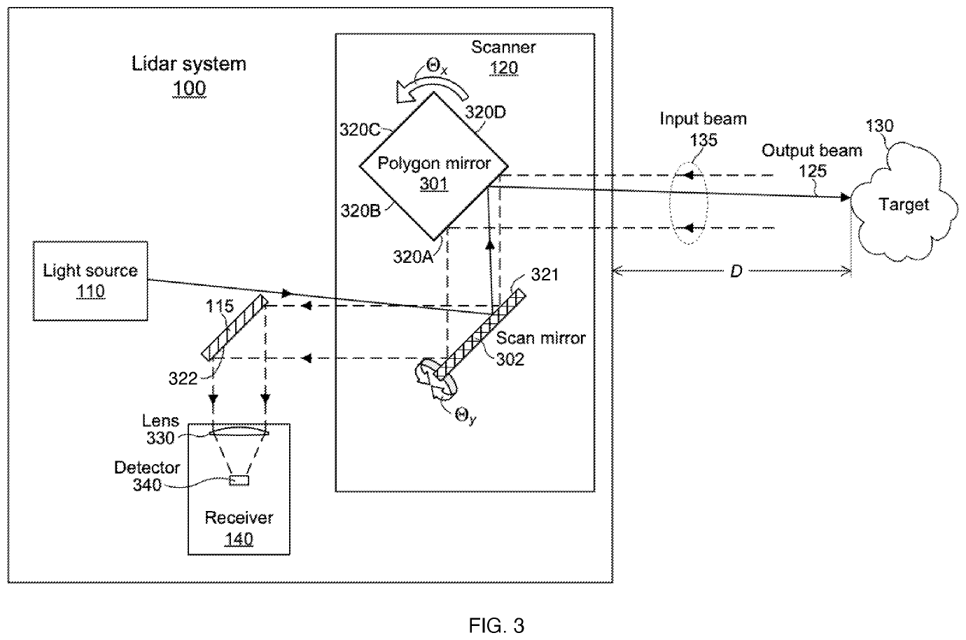

In particular embodiments, a lidar system 100 may be an FMCW lidar system where the emitted light from the light source 110 (e.g., output beam 125 in FIG. 1 or FIG. 3) includes frequency-modulated light. A pulsed lidar system is a type of lidar system 100 in which the light source 110 emits pulses of light, and the distance to a remote target 130 is determined based on the round-trip time-of-flight for a pulse of light to travel to the target 130 and back. Another type of lidar system 100 is a frequency-modulated lidar system, which may be referred to as a frequency-modulated continuous-wave (FMCW) lidar system. An FMCW lidar system uses frequency-modulated light to determine the distance to a remote target 130 based on a frequency of received light (which includes emitted light scattered by the remote target) relative to a frequency of local-oscillator (LO) light. A round-trip time for the emitted light to travel to a target 130 and back to the lidar system may correspond to a frequency difference between the received scattered light and the LO light. A larger frequency difference may correspond to a longer round-trip time and a greater distance to the target 130.

A light source 110 for an FMCW lidar system may include at least one instance of (i) a direct-emitter laser diode, (ii) a seed laser diode followed by an SOA, (iii) a seed laser diode followed by a fiber-optic amplifier, or (iv) a seed laser diode followed by an SOA and then a fiber-optic amplifier. A seed laser diode or a direct-emitter laser diode may be operated in a CW manner (e.g., by driving the laser diode with a substantially constant DC current), and a frequency modulation may be provided by an external modulator (e.g., an electro-optic phase modulator may apply a frequency modulation to seed-laser light). Alternatively, a frequency modulation may be produced by applying a current modulation to a seed laser diode or a direct-emitter laser diode. The current modulation (which may be provided along with a DC bias current) may produce a corresponding refractive-index modulation in the laser diode, which results in a frequency modulation of the light emitted by the laser diode. The current-modulation component (and the corresponding frequency modulation) may have any suitable frequency or shape (e.g., piecewise linear, sinusoidal, triangle-wave, or sawtooth). For example, the current-modulation component (and the resulting frequency modulation of the emitted light) may increase or decrease monotonically over a particular time interval. As another example, the current-modulation component may include a triangle or sawtooth wave with an electrical current that increases or decreases linearly over a particular time interval, and the light emitted by the laser diode may include a corresponding frequency modulation in which the optical frequency increases or decreases approximately linearly over the particular time interval. For example, a light source 110 that emits light with a linear frequency change of 200 MHz over a 2-μs time interval may be referred to as having a frequency modulation m of 10¹⁴ Hz/s (or, 100 MHz/μs).

In addition to producing frequency-modulated emitted light, a light source 110 may also produce frequency-modulated local-oscillator (LO) light. The LO light may be coherent with the emitted light, and the frequency modulation of the LO light may match that of the emitted light. The LO light may be produced by splitting off a portion of the emitted light prior to the emitted light exiting the lidar system. Alternatively, the LO light may be produced by a seed laser diode or a direct-emitter laser diode that is part of the light source 110. For example, the LO light may be emitted from the back facet of a seed laser diode or a direct-emitter laser diode, or the LO light may be split off from the seed light emitted from the front facet of a seed laser diode. The received light (e.g., emitted light that is scattered by a target 130) and the LO light may each be frequency modulated, with a frequency difference or offset that corresponds to the distance to the target 130. For a linearly chirped light source (e.g., a frequency modulation that produces a linear change in frequency with time), the larger the frequency difference is between the received light and the LO light, the farther away the target 130 is located.

A frequency difference between received light and LO light may be determined by mixing the received light with the LO light (e.g., by coupling the two beams onto a detector so they are coherently mixed together at the detector) and determining the resulting beat frequency. For example, a photocurrent signal produced by an APD may include a beat signal resulting from the coherent mixing of the received light and the LO light, and a frequency of the beat signal may correspond to the frequency difference between the received light and the LO light. The photocurrent signal from an APD (or a voltage signal that corresponds to the photocurrent signal) may be analyzed using a frequency-analysis technique (e.g., a fast Fourier transform (FFT) technique) to determine the frequency of the beat signal. If a linear frequency modulation m (e.g., in units of Hz/s) is applied to a CW laser, then the round-trip time T may be related to the frequency difference Δf between the received scattered light and the LO light by the expression T=Δf/m. Additionally, the distance D from the target 130 to the lidar system 100 may be expressed as D=(Δf/m)·c/2, where c is the speed of light. For example, for a light source 110 with a linear frequency modulation of 10¹⁴ Hz/s, if a frequency difference (between the received scattered light and the LO light) of 33 MHz is measured, then this corresponds to a round-trip time of approximately 330 ns and a distance to the target of approximately 50 meters. As another example, a frequency difference of 133 MHz corresponds to a round-trip time of approximately 1.33 μs and a distance to the target of approximately 200 meters. A receiver or processor of an FMCW lidar system may determine a frequency difference between received scattered light and LO light, and the distance to a target may be determined based on the frequency difference. The frequency difference Δf between received scattered light and LO light corresponds to the round-trip time T (e.g., through the relationship T=Δf/m), and determining the frequency difference may correspond to or may be referred to as determining the round-trip time.

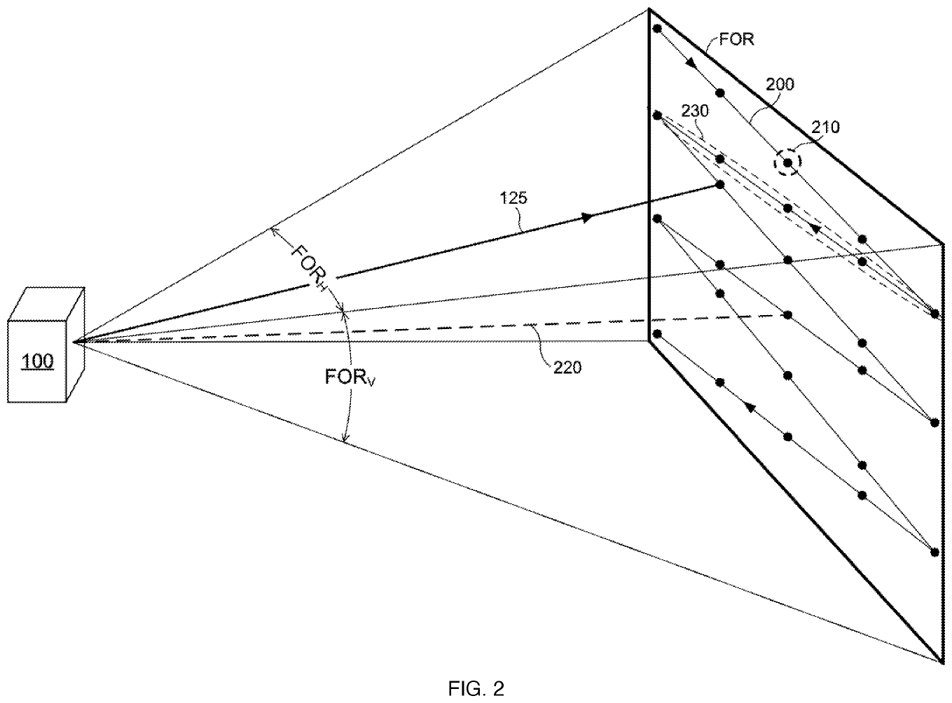

FIG. 2 illustrates an example scan pattern 200 produced by a lidar system 100. A scanner 120 of the lidar system 100 may scan the output beam 125 (which may include multiple emitted optical signals) along a scan pattern 200 that is contained within a field of regard (FOR) of the lidar system 100. A scan pattern 200 (which may be referred to as an optical scan pattern, optical scan path, scan path, or scan) may represent a path or course followed by output beam 125 as it is scanned across all or part of a FOR. Each traversal of a scan pattern 200 may correspond to the capture of a single frame or a single point cloud. In particular embodiments, a lidar system 100 may be configured to scan output optical beam 125 along one or more particular scan patterns 200. In particular embodiments, a scan pattern 200 may scan across any suitable field of regard (FOR) having any suitable horizontal FOR (FOR_{H}) and any suitable vertical FOR (FOR_{V}). For example, a scan pattern 200 may have a field of regard represented by angular dimensions (e.g., FOR_{H}×FOR_{V}) 40°×30°, 90°×40°, or 60°×15°. As another example, a scan pattern 200 may have a FOR_{H} greater than or equal to 10°, 25°, 30°, 40°, 60°, 90°, or 120°. As another example, a scan pattern 200 may have a FOR_{V} greater than or equal to 2°, 5°, 10°, 15°, 30°, or 45°.

In the example of FIG. 2, reference line 220 represents a center of the field of regard of scan pattern 200. In particular embodiments, reference line 220 may have any suitable orientation, such as for example, a horizontal angle of 0° (e.g., reference line 220 may be oriented straight ahead) and a vertical angle of 0° (e.g., reference line 220 may have an inclination of 0°), or reference line 220 may have a nonzero horizontal angle or a nonzero inclination (e.g., a vertical angle of +10° or −10°). In FIG. 2, if the scan pattern 200 has a field of regard, then scan pattern 200 covers a ±30° horizontal range with respect to reference line 220 and a ±7.5° vertical range with respect to reference line 220. Additionally, optical beam 125 in FIG. 2 has an orientation of approximately −15° horizontal and +3° vertical with respect to reference line 220. Optical beam 125 may be referred to as having an azimuth of −15° and an altitude of +3° relative to reference line 220. In particular embodiments, an azimuth (which may be referred to as an azimuth angle) may represent a horizontal angle with respect to reference line 220, and an altitude (which may be referred to as an altitude angle, elevation, or elevation angle) may represent a vertical angle with respect to reference line 220.

In particular embodiments, a scan pattern 200 may include multiple pixels 210, and each pixel 210 may be associated with one or more laser pulses or one or more distance measurements. Additionally, a scan pattern 200 may include multiple scan lines 230, where each scan line represents one scan across at least part of a field of regard, and each scan line 230 may include multiple pixels 210. In FIG. 2, scan line 230 includes five pixels 210 and corresponds to an approximately horizontal scan across the FOR from right to left, as viewed from the lidar system 100. In particular embodiments, a cycle of scan pattern 200 may include a total of Pₓ×P_{y} pixels 210 (e.g., a two-dimensional distribution of Pₓ by P_{y} pixels). As an example, scan pattern 200 may include a distribution with dimensions of approximately 100-2,000 pixels 210 along a horizontal direction and approximately 4-400 pixels 210 along a vertical direction. As another example, scan pattern 200 may include a distribution of 1,000 pixels 210 along the horizontal direction by 64 pixels 210 along the vertical direction (e.g., the frame size is 1000×64 pixels) for a total of 64,000 pixels per cycle of scan pattern 200. In particular embodiments, the number of pixels 210 along a horizontal direction may be referred to as a horizontal resolution of scan pattern 200, and the number of pixels 210 along a vertical direction may be referred to as a vertical resolution. As an example, scan pattern 200 may have a horizontal resolution of greater than or equal to 100 pixels 210 and a vertical resolution of greater than or equal to 4 pixels 210. As another example, scan pattern 200 may have a horizontal resolution of 100-2,000 pixels 210 and a vertical resolution of 4-400 pixels 210.

In particular embodiments, a pixel 210 may refer to a data element that includes (i) distance information (e.g., a distance from a lidar system 100 to a target 130 from which an associated pulse of light was scattered) or (ii) an elevation angle and an azimuth angle associated with the pixel (e.g., the elevation and azimuth angles along which the associated pulse of light was emitted). Each pixel 210 may be associated with a distance (e.g., a distance to a portion of a target 130 from which an associated laser pulse was scattered) or one or more angular values. As an example, a pixel 210 may be associated with a distance value and two angular values (e.g., an azimuth and altitude) that represent the angular location of the pixel 210 with respect to the lidar system 100. A distance to a portion of target 130 may be determined based at least in part on a time-of-flight measurement for a corresponding pulse. An angular value (e.g., an azimuth or altitude) may correspond to an angle (e.g., relative to reference line 220) of output beam 125 (e.g., when a corresponding pulse is emitted from lidar system 100) or an angle of input beam 135 (e.g., when an input signal is received by lidar system 100). In particular embodiments, an angular value may be determined based at least in part on a position of a component of scanner 120. As an example, an azimuth or altitude value associated with a pixel 210 may be determined from an angular position of one or more corresponding scanning mirrors of scanner 120.

FIG. 3 illustrates an example lidar system 100 with an example rotating polygon mirror 301. In particular embodiments, a scanner 120 may include a polygon mirror 301 configured to scan output beam 125 along a particular direction. In the example of FIG. 3, scanner 120 includes two scanning mirrors: (1) a polygon mirror 301 that rotates along the Θₓ direction and (2) a scanning mirror 302 that oscillates back and forth along the Θ_{y} direction. The output beam 125 from light source 110, which passes alongside mirror 115, is reflected by reflecting surface 321 of scan mirror 302 and is then reflected by a reflecting surface (e.g., surface 320A, 320B, 320C, or 320D) of polygon mirror 301. Scattered light from a target 130 returns to the lidar system 100 as input beam 135. The input beam 135 reflects from polygon mirror 301, scan mirror 302, and mirror 115, which directs input beam 135 through focusing lens 330 and to the detector 340 of receiver 140. As shown in FIG. 3, scan mirror 302 includes reflecting surface 321 and mirror 115 includes reflecting surface 322. The detector 340 may be a PN photodiode, a PIN photodiode, an APD, an SPAD, or any other suitable detector. A reflecting surface 320 (which may be referred to as a reflective surface) may include a reflective metallic coating (e.g., gold, silver, or aluminum) or a reflective dielectric coating, and the reflecting surface 320 may have any suitable reflectivity R at an operating wavelength of the light source 110 (e.g., R greater than or equal to 70%, 80%, 90%, 95%, 98%, or 99%).

In particular embodiments, a polygon mirror 301 may be configured to rotate along a Θₓ or Θ_{y} direction and scan output beam 125 along a substantially horizontal or vertical direction, respectively. A rotation along a Θₓ direction may refer to a rotational motion of mirror 301 that results in output beam 125 scanning along a substantially horizontal direction. Similarly, a rotation along a Θ_{y} direction may refer to a rotational motion that results in output beam 125 scanning along a substantially vertical direction. In FIG. 3, mirror 301 is a polygon mirror that rotates along the Θₓ direction and scans output beam 125 along a substantially horizontal direction, and mirror 302 pivots along the Θ_{y} direction and scans output beam 125 along a substantially vertical direction. In particular embodiments, a polygon mirror 301 may be configured to scan output beam 125 along any suitable direction. As an example, a polygon mirror 301 may scan output beam 125 at any suitable angle with respect to a horizontal or vertical direction, such as for example, at an angle of approximately 0°, 10°, 20°, 30°, 45°, 60°, 80°, or 90° with respect to a horizontal or vertical direction.

In particular embodiments, a polygon mirror 301 may refer to a multi-sided object having reflective surfaces 320 on two or more of its sides or faces. As an example, a polygon mirror may include any suitable number of reflective faces (e.g., 2, 3, 4, 5, 6, 7, 8, or 10 faces), where each face includes a reflective surface 320. A polygon mirror 301 may have a cross-sectional shape of any suitable polygon, such as for example, a triangle (with three reflecting surfaces 320), square (with four reflecting surfaces 320), pentagon (with five reflecting surfaces 320), hexagon (with six reflecting surfaces 320), heptagon (with seven reflecting surfaces 320), or octagon (with eight reflecting surfaces 320). In FIG. 3, the polygon mirror 301 has a substantially square cross-sectional shape and four reflecting surfaces (320A, 320B, 320C, and 320D). The polygon mirror 301 in FIG. 3 may be referred to as a square mirror, a cube mirror, or a four-sided polygon mirror. In FIG. 3, the polygon mirror 301 may have a shape similar to a cube, cuboid, or rectangular prism. Additionally, the polygon mirror 301 may have a total of six sides, where four of the sides include faces with reflective surfaces (320A, 320B, 320C, and 320D).

In particular embodiments, a polygon mirror 301 may be continuously rotated in a clockwise or counter-clockwise rotation direction about a rotation axis of the polygon mirror 301. The rotation axis may correspond to a line that is perpendicular to the plane of rotation of the polygon mirror 301 and that passes through the center of mass of the polygon mirror 301. In FIG. 3, the polygon mirror 301 rotates in the plane of the drawing, and the rotation axis of the polygon mirror 301 is perpendicular to the plane of the drawing. An electric motor may be configured to rotate a polygon mirror 301 at a substantially fixed frequency (e.g., a rotational frequency of approximately 1 Hz (or 1 revolution per second), 10 Hz, 50 Hz, 100 Hz, 500 Hz, or 1,000 Hz). As an example, a polygon mirror 301 may be mechanically coupled to an electric motor (e.g., a synchronous electric motor) which is configured to spin the polygon mirror 301 at a rotational speed of approximately 160 Hz (or, 9600 revolutions per minute (RPM)).

In particular embodiments, output beam 125 may be reflected sequentially from the reflective surfaces 320A, 320B, 320C, and 320D as the polygon mirror 301 is rotated. This results in the output beam 125 being scanned along a particular scan axis (e.g., a horizontal or vertical scan axis) to produce a sequence of scan lines, where each scan line corresponds to a reflection of the output beam 125 from one of the reflective surfaces of the polygon mirror 301. In FIG. 3, the output beam 125 reflects off of reflective surface 320A to produce one scan line. Then, as the polygon mirror 301 rotates, the output beam 125 reflects off of reflective surfaces 320B, 320C, and 320D to produce a second, third, and fourth respective scan line. In particular embodiments, a lidar system 100 may be configured so that the output beam 125 is first reflected from polygon mirror 301 and then from scan mirror 302 (or vice versa). As an example, an output beam 125 from light source 110 may first be directed to polygon mirror 301, where it is reflected by a reflective surface of the polygon mirror 301, and then the output beam 125 may be directed to scan mirror 302, where it is reflected by reflective surface 321 of the scan mirror 302. In the example of FIG. 3, the output beam 125 is reflected from the polygon mirror 301 and the scan mirror 302 in the reverse order. In FIG. 3, the output beam 125 from light source 110 is first directed to the scan mirror 302, where it is reflected by reflective surface 321, and then the output beam 125 is directed to the polygon mirror 301, where it is reflected by reflective surface 320A.

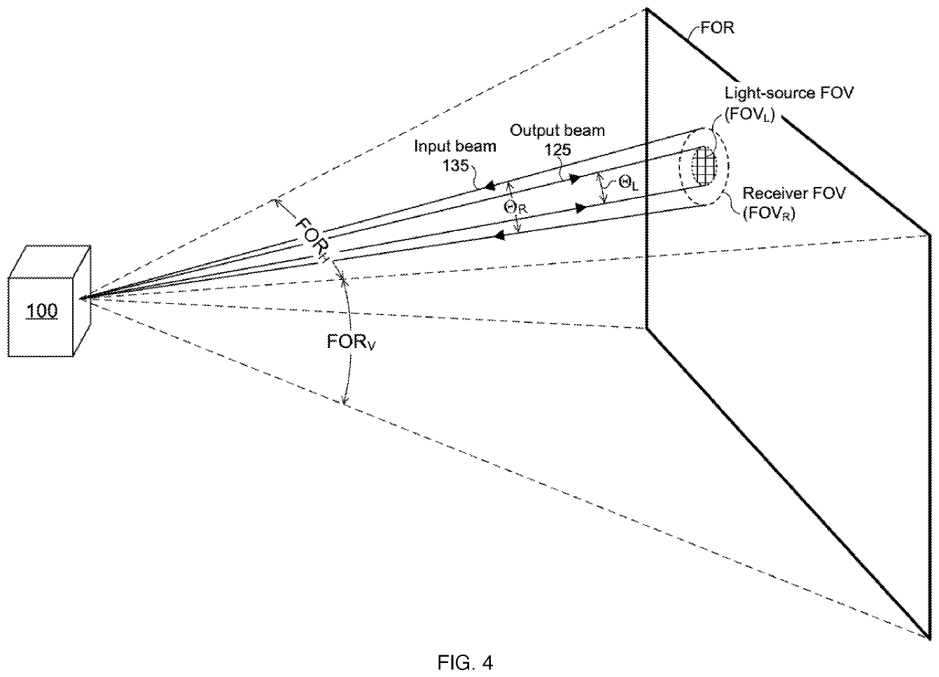

FIG. 4 illustrates an example light-source field of view (FOV_{L}) and receiver field of view (FOV_{R}) for a lidar system 100. A light source 110 of lidar system 100 may emit pulses of light as the FOV_{L} and FOV_{R} are scanned by scanner 120 across a field of regard (FOR). In particular embodiments, a light-source field of view may refer to an angular cone illuminated by the light source 110 at a particular instant of time. Similarly, a receiver field of view may refer to an angular cone over which the receiver 140 may receive or detect light at a particular instant of time, and any light outside the receiver field of view may not be received or detected. As an example, as the light-source field of view is scanned across a field of regard, a portion of a pulse of light emitted by the light source 110 may be sent downrange from lidar system 100, and the pulse of light may be sent in the direction that the FOV_{L} is pointing at the time the pulse is emitted. The pulse of light may scatter off a target 130, and the receiver 140 may receive and detect a portion of the scattered light that is directed along or contained within the FOV_{R}.

In particular embodiments, scanner 120 may be configured to scan both a light-source field of view and a receiver field of view across a field of regard of the lidar system 100. Multiple pulses of light may be emitted and detected as the scanner 120 scans the FOV_{L} and FOV_{R} across the field of regard of the lidar system 100 while tracing out a scan pattern 200. In particular embodiments, the light-source field of view and the receiver field of view may be scanned synchronously with respect to one another, so that as the FOV_{L} is scanned across a scan pattern 200, the FOV_{R} follows substantially the same path at the same scanning speed. Additionally, the FOV_{L} and FOV_{R} may maintain the same relative position to one another as they are scanned across the field of regard. As an example, the FOV_{L} may be substantially overlapped with or centered inside the FOV_{R} (as illustrated in FIG. 4), and this relative positioning between FOV_{L} and FOV_{R} may be maintained throughout a scan. As another example, the FOV_{R} may lag behind the FOV_{L} by a particular, fixed amount throughout a scan (e.g., the FOV_{R} may be offset from the FOV_{L} in a direction opposite the scan direction).

In particular embodiments, the FOV_{L} may have an angular size or extent Θ_{L} that is substantially the same as or that corresponds to the divergence of the output beam 125, and the FOV_{R} may have an angular size or extent Θ_{R} that corresponds to an angle over which the receiver 140 may receive and detect light. In particular embodiments, the receiver field of view may be any suitable size relative to the light-source field of view. As an example, the receiver field of view may be smaller than, substantially the same size as, or larger than the angular extent of the light-source field of view. In particular embodiments, the light-source field of view may have an angular extent of less than or equal to 50 milliradians, and the receiver field of view may have an angular extent of less than or equal to 50 milliradians. The FOV_{L} may have any suitable angular extent Θ_{L}, such as for example, approximately 0.1 mrad, 0.2 mrad, 0.5 mrad, 1 mrad, 1.5 mrad, 2 mrad, 3 mrad, 5 mrad, 10 mrad, 20 mrad, 40 mrad, or 50 mrad. Similarly, the FOV_{R} may have any suitable angular extent OR, such as for example, approximately 0.1 mrad, 0.2 mrad, 0.5 mrad, 1 mrad, 1.5 mrad, 2 mrad, 3 mrad, 5 mrad, 10 mrad, 20 mrad, 40 mrad, or 50 mrad. In particular embodiments, the light-source field of view and the receiver field of view may have approximately equal angular extents. As an example, Θ_{L} and Θ_{R} may both be approximately equal to 1 mrad, 2 mrad, or 4 mrad. In particular embodiments, the receiver field of view may be larger than the light-source field of view, or the light-source field of view may be larger than the receiver field of view. As an example, Θ_{L} may be approximately equal to 3 mrad, and Θ_{R} may be approximately equal to 4 mrad. As another example, Θ_{R} may be approximately L times larger than Θ_{L}, where L is any suitable factor, such as for example, 1.1, 1.2, 1.5, 2, 3, 5, or 10.

In particular embodiments, a pixel 210 may represent or may correspond to a light-source field of view or a receiver field of view. As the output beam 125 propagates from the light source 110, the diameter of the output beam 125 (as well as the size of the corresponding pixel 210) may increase according to the beam divergence Θ_{L}. As an example, if the output beam 125 has a Θ_{L} of 2 mrad, then at a distance of 100 m from the lidar system 100, the output beam 125 may have a size or diameter of approximately 20 cm, and a corresponding pixel 210 may also have a corresponding size or diameter of approximately 20 cm. At a distance of 200 m from the lidar system 100, the output beam 125 and the corresponding pixel 210 may each have a diameter of approximately 40 cm.

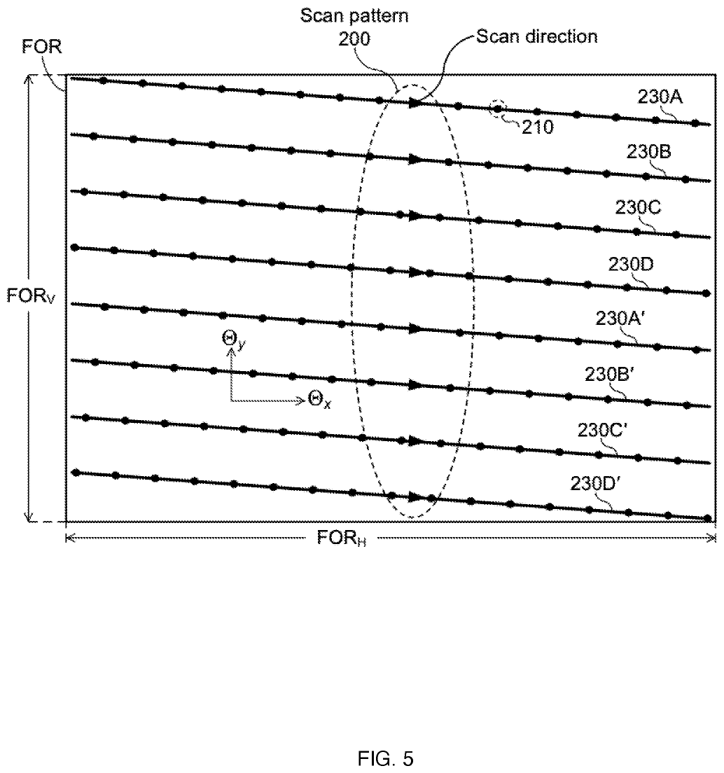

FIG. 5 illustrates an example unidirectional scan pattern 200 that includes multiple pixels 210 and multiple scan lines 230. In particular embodiments, scan pattern 200 may include any suitable number of scan lines 230 (e.g., approximately 1, 2, 5, 10, 20, 50, 100, 500, or 1,000 scan lines), and each scan line 230 of a scan pattern 200 may include any suitable number of pixels 210 (e.g., 1, 2, 5, 10, 20, 50, 100, 200, 500, 1,000, 2,000, or 5,000 pixels). The scan pattern 200 illustrated in FIG. 5 includes eight scan lines 230, and each scan line 230 includes approximately 16 pixels 210. In particular embodiments, a scan pattern 200 where the scan lines 230 are scanned in two directions (e.g., alternately scanning from right to left and then from left to right) may be referred to as a bidirectional scan pattern 200, and a scan pattern 200 where the scan lines 230 are scanned in the same direction may be referred to as a unidirectional scan pattern 200. The scan pattern 200 in FIG. 2 may be referred to as a bidirectional scan pattern, and the scan pattern 200 in FIG. 5 may be referred to as a unidirectional scan pattern 200 where each scan line 230 travels across the FOR in substantially the same direction (e.g., approximately from left to right as viewed from the lidar system 100). In particular embodiments, scan lines 230 of a unidirectional scan pattern 200 may be directed across a FOR in any suitable direction, such as for example, from left to right, from right to left, from top to bottom, from bottom to top, or at any suitable angle (e.g., at a 0°, 5°, 10°, 30°, or 45° angle) with respect to a horizontal or vertical axis. In particular embodiments, each scan line 230 in a unidirectional scan pattern 200 may be a separate line that is not directly connected to a previous or subsequent scan line 230.

In particular embodiments, a unidirectional scan pattern 200 may be produced by a scanner 120 that includes a polygon mirror (e.g., polygon mirror 301 of FIG. 3), where each scan line 230 is associated with a particular reflective surface 320 of the polygon mirror. As an example, reflective surface 320A of polygon mirror 301 in FIG. 3 may produce scan line 230A in FIG. 5. Similarly, as the polygon mirror 301 rotates, reflective surfaces 320B, 320C, and 320D may successively produce scan lines 230B, 230C, and 230D, respectively. Additionally, for a subsequent revolution of the polygon mirror 301, the scan lines 230A′, 230B′, 230C′, and 230D′ may be successively produced by reflections of the output beam 125 from reflective surfaces 320A, 320B, 320C, and 320D, respectively. In particular embodiments, N successive scan lines 230 of a unidirectional scan pattern 200 may correspond to one full revolution of an N-sided polygon mirror. As an example, the four scan lines 230A, 230B, 230C, and 230D in FIG. 5 may correspond to one full revolution of the four-sided polygon mirror 301 in FIG. 3. Additionally, a subsequent revolution of the polygon mirror 301 may produce the next four scan lines 230A′, 230B′, 230C′, and 230D′ in FIG. 5.

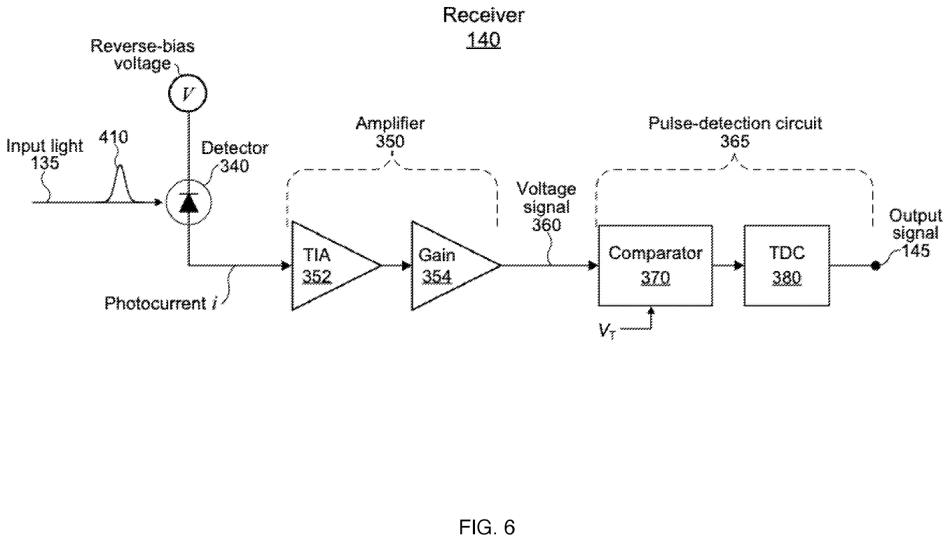

FIG. 6 illustrates an example receiver 140 that includes a detector 340, amplifier 350, and pulse-detection circuit 365. An amplifier 350 and a pulse-detection circuit 365 may include circuitry that receives an electrical-current signal (e.g., photocurrent i) from a detector 340 and performs current-to-voltage conversion, signal amplification, sampling, filtering, signal conditioning, analog-to-digital conversion, time-to-digital conversion, pulse detection, threshold detection, rising-edge detection, falling-edge detection, or pulse time-of-arrival determination. An electronic amplifier 350 may include one or more transimpedance amplifiers (TIAs) 352 or one or more voltage-gain circuits 354, and a pulse-detection circuit 365 may include one or more comparators 370 or one or more time-to-digital converters (TDCs) 380. In FIG. 6, the amplifier 350 includes one TIA 352 and one voltage-gain circuit 354, and the pulse-detection circuit 365 includes one comparator 370 and one TDC 380. The output signal 145 from a pulse-detection circuit 365 may be sent to a controller 150 (shown in FIG. 1), and based on the output signal 145, the controller 150 may determine (i) whether an optical signal (e.g., a pulse of light 410) has been received by a detector 340 or (ii) a time associated with receipt of an optical signal by a detector 340 (e.g., a time of arrival of a received pulse of light 410). Although single instances of many components are shown in and described with respect to FIG. 6, for example receiver 140, in various embodiments, receiver 140 can include multiple instances of the components shown in FIG. 6, such as multiple instances of detector 340, amplifier 350, and/or pulse-detection circuit 365, for example, to detect different light pulses.

An amplifier 350 and a pulse-detection circuit 365 may be located within a receiver 140, or all or part of an amplifier 350 or pulse-detection circuit 365 may be located external to the receiver. For example, an amplifier 350 may be part of a receiver 140, and a pulse-detection circuit 365 may be located external to the receiver 140 (e.g., within a controller 150 located external to the receiver 140). As another example, an amplifier 350 and a pulse-detection circuit 365 may be located within a receiver 140, as illustrated in FIG. 6. A controller 150 may be located within a receiver 140, external to the receiver 140, or partially within and partially external to the receiver 140. For example, a controller 150 may be located external to the receiver 140, and an output signal 145 may be sent (e.g., via a high-speed data link) to the controller 150 for processing or analysis. As another example, a controller 150 may include an ASIC that is located within the receiver 140 (e.g., the ASIC may include an amplifier 350 or a pulse-detection circuit 365, as well as additional circuitry configured to receive and process the output signal 145 from the pulse-detection circuit 365). In addition to an ASIC located within the receiver 140, the controller 150 may also include one or more additional processors located external to the receiver 140 or external to the lidar system 100 (e.g., a processor may receive data from an ASIC and process the data to produce point clouds, identify an object located ahead of a vehicle, or provide control signals to a vehicle's driving systems).

In FIG. 6, the detector 340 receives input light 135 and produces a photocurrent that is sent to the amplifier 350. The photocurrent i produced by the detector 340 in response to the input light 135 may be referred to as a photocurrent signal, electrical-current signal, electrical current, detector current, or current. The detector 340 may be a PN photodiode, a PIN photodiode, an APD, a SPAD, or any other suitable detector. The detector 340 may have an active region or an avalanche-multiplication region that includes indium gallium arsenide (InGaAs), germanium (Ge), silicon (Si), germanium silicon (GeSi), germanium silicon tin (GeSiSn), or any other suitable detector material. The detector 340 may be configured to detect light at one or more operating wavelengths of a lidar system 100, such as for example at a wavelength of approximately 905 nm, 1200 nm, 1400 nm, 1500 nm, or 1550 nm, or at one or more wavelengths in the 1400-1600 nm range. For example, a light source 110 may produce an output beam 125 having a wavelength of approximately 905 nm, and the detector 340 may be a silicon photodetector that detects 905 nm light. As another example, a light source 110 may emit light at one or more wavelengths from 1400 nm to 1600 nm, and the detector 340 may be a InGaAs APD that detects light in the 1400-1600 nm range. A receiver 140 may include a detector 340 with a single detector element (as illustrated in FIG. 6), or a receiver 140 may include a one-dimensional or two-dimensional detector array with multiple detector elements, as described below.

The receiver 140 in FIG. 6 includes a detector 340 coupled to an electronic amplifier 350, which in turn, is coupled to a pulse-detection circuit 365. The detector 340 may also be coupled to a voltage source that supplies a reverse-bias voltage V to the detector 340, as illustrated in FIG. 6. The detector 340 receives input light 135 and produces a photocurrent i that is sent to the amplifier 350, and the amplifier 350 produces a voltage signal 360 that is sent to the pulse-detection circuit 365. In the example of FIG. 6, the input light 135 includes a received pulse of light 410 (which may include a portion of a pulse of light 400 emitted by a light source 110 and scattered by a remote target 130). The photocurrent signal i may include a pulse of electrical current that corresponds to the received pulse of light 410. The pulse of current and the pulse of light 410 corresponding to one another may refer to the pulse of current and the pulse of light 410 having similar pulse characteristics (e.g., similar rise times, fall times, shapes, or durations). For example, the pulse of electrical current may have a rise time, fall time, or duration that is approximately equal to or somewhat greater than that of the pulse of light 410 (e.g., a rise time, fall time, or duration between 1× and 1.5× that of the pulse of light 410). The electrical current may have a somewhat longer rise time, fall time, or duration due to a limited electrical bandwidth of the detector 340 or the detector circuitry. As another example, the pulse of light 410 may have a 1-ns rise time and a 4-ns duration, and the pulse of electrical current may have a 1.2-ns rise time and a 5-ns duration.

In particular embodiments, an amplifier 350 may include a TIA 352 configured to receive a photocurrent signal i from a detector 340 and produce a voltage signal 360 that corresponds to the received photocurrent. As an example, in response to a received pulse of light 410 (e.g., light from an emitted pulse of light 400 that is scattered by a remote target 130), a detector 340 may produce photocurrent i that includes a pulse of electrical current corresponding to the received pulse of light 410. A TIA 352 may receive the electrical-current pulse from the detector 340 and produce a voltage signal 360 that includes a voltage pulse corresponding to the received current pulse. The voltage pulse and the current pulse corresponding to one another may refer to the voltage pulse and the current pulse having similar rise times, fall times, shapes, durations, or other similar pulse characteristics. For example, the voltage pulse may have a rise time, fall time, or duration that is between 1× and 1.5× that of the pulse of electrical current. The voltage pulse may have a somewhat longer rise time, fall time, or duration due to a limited electrical bandwidth of the TIA circuitry. As another example, the pulse of electrical current may have a 1.2-ns rise time and a 5-ns duration, and the corresponding voltage pulse may have a 1.5-ns rise time and a 7-ns duration.

A TIA 352 may be referred to as a current-to-voltage converter, and producing a voltage signal from a received photocurrent signal may be referred to as performing current-to-voltage conversion. The transimpedance gain or amplification of a TIA 352 may be expressed in units of ohms (Ω), or equivalently volts per ampere (V/A). For example, if a TIA 352 has a gain of 100 V/A, then for a photocurrent i with a peak current of 10 μA, the TIA 352 may produce a voltage signal 360 with a corresponding peak voltage of approximately 1 mV. In particular embodiments, in addition to acting as a current-to-voltage converter, a TIA 352 may also act as an electronic filter (e.g., a low-pass, high-pass, or band-pass filter). As an example, a TIA 352 may be configured as a low-pass filter that removes or attenuates high-frequency electrical noise by attenuating signals above a particular frequency (e.g., above 1 MHz, 10 MHz, 20 MHz, 50 MHz, 100 MHz, 200 MHz, 300 MHz, 1 GHz, or any other suitable frequency).

In particular embodiments, an amplifier 350 may not include a separate voltage-gain circuit. For example, a TIA 352 may produce a voltage signal 360 that is directly coupled to a pulse-detection circuit 365 without an intervening gain circuit. In other embodiments, in addition to a TIA 352, an electronic amplifier 350 may also include a voltage-gain circuit 354. The electronic amplifier 350 in FIG. 6 includes a TIA 352 followed by a voltage-gain circuit 354 (which may be referred to as a gain circuit or a voltage amplifier). The TIA 352 may amplify the photocurrent i to produce an intermediate voltage signal (e.g., a voltage pulse), and the voltage-gain circuit 354 may amplify the intermediate voltage signal to produce a voltage signal 360 (e.g., an amplified voltage pulse) that is supplied to a pulse-detection circuit 365. As an example, a gain circuit 354 may include one or more voltage-amplification stages that amplify a voltage signal received from a TIA 352. For example, the gain circuit 354 may receive a voltage pulse from a TIA 352, and the gain circuit 354 may amplify the voltage pulse by any suitable amount, such as for example, by a gain of approximately 3 dB, 10 dB, 20 dB, 30 dB, 40 dB, or 50 dB. Additionally, the gain circuit 354 may be configured to also act as an electronic filter (e.g., a low-pass, high-pass, or band-pass filter) to remove or attenuate electrical noise.

In particular embodiments, a pulse-detection circuit 365 may include a comparator 370 configured to receive a voltage signal 360 from a TIA 352 or gain circuit 354 and produce an electrical-edge signal (e.g., a rising edge or a falling edge) when the received voltage signal 360 rises above or falls below a particular threshold voltage V_{T}. As an example, when a received voltage signal 360 rises above V_{T}, a comparator 370 may produce a rising-edge digital-voltage signal (e.g., a signal that steps from approximately 0 V to approximately 2.5 V, 3.3 V, 5 V, or any other suitable digital-high level). Additionally or alternatively, when a received voltage signal 360 falls below V_{T}, a comparator 370 may produce a falling-edge digital-voltage signal (e.g., a signal that steps down from approximately 2.5 V, 3.3 V, 5 V, or any other suitable digital-high level to approximately 0 V). The voltage signal 360 received by the comparator 370 may be received from a TIA 352 or gain circuit 354 and may correspond to a photocurrent signal i produced by a detector 340. As an example, the voltage signal 360 received by the comparator 370 may include a voltage pulse that corresponds to an electrical-current pulse produced by the detector 340 in response to a received pulse of light 410. The voltage signal 360 received by the comparator 370 may be an analog signal, and an electrical-edge signal produced by the comparator 370 may be a digital signal.

In particular embodiments, a pulse-detection circuit 365 may include a time-to-digital converter (TDC) 380 configured to receive an electrical-edge signal from a comparator 370 and produce an electrical output signal (e.g., a digital signal, a digital word, or a digital value) that represents a time when the edge signal is received from the comparator 370. The time when the edge signal is received from the comparator 370 may correspond to a time of arrival of a received pulse of light 410, which may be used to determine a round-trip time of flight for a pulse of light to travel from a lidar system 100 to a target 130 and back to the lidar system 100. The output of the TDC 380 may include one or more numerical values, where each numerical value (which may be referred to as a numerical time value, a time value, a digital value, or a digital time value) corresponds to a time interval determined by the TDC 380. A TDC 380 may have an internal counter or clock with any suitable period, such as for example, 5 ps, 10 ps, 15 ps, 20 ps, 30 ps, 50 ps, 100 ps, 0.5 ns, 1 ns, 2 ns, 5 ns, or 10 ns. As an example, the TDC 380 may have an internal counter or clock with a 20-ps period, and the TDC 380 may determine that an interval of time between emission and receipt of an optical pulse is equal to 25,000 time periods, which corresponds to a time interval of approximately 0.5 microseconds. The TDC 380 may send an output signal 145 that includes the numerical value “25000” to a controller 150 of the lidar system 100. In particular embodiments, a lidar system 100 may include a controller 150 that determines a distance from the lidar system 100 to a target 130 based on one or more intervals of time determined by one or more TDCs 380. As an example, the controller 150 may receive a numerical value (e.g., “25000”) from the TDC 380, and based on the received value, the controller may determine a time of arrival of a received pulse of light 410. Additionally, the controller 150 may determine the distance from the lidar system to the target 130 based on the time of arrival of the received pulse of light 410.

In particular embodiments, determining an interval of time between emission and receipt of a pulse of light may be based on determining (1) a time associated with the emission of a pulse of light 400 and (2) a time when a received pulse of light 410 (which may include a portion of the emitted pulse of light 400 scattered by a target 130) is detected by a receiver 140. As an example, a TDC 380 may count the number of time periods, clock cycles, or fractions of clock cycles between an electrical edge associated with emission of a pulse of light and an electrical edge associated with detection of scattered light from the emitted pulse of light. Determining when scattered light from the pulse of light is detected by receiver 140 may be based on determining one or more times for one or more rising or falling edges (e.g., rising or falling edges produced by one or more comparators 370) associated with the detected pulse of light. In particular embodiments, determining a time associated with emission of a pulse of light 400 may be based on an electrical trigger signal. As an example, a light source 110 may produce an electrical trigger signal for each pulse of light that is emitted, or an electrical device (e.g., controller 150) may provide a trigger signal to the light source 110 to initiate the emission of each pulse of light. A trigger signal associated with emission of an optical pulse may be provided to TDC 380, and a rising edge or falling edge of the trigger signal may correspond to a time when the optical pulse is emitted. In particular embodiments, a time associated with emission of an optical pulse may be determined based on an optical trigger signal. As an example, a time associated with the emission of a pulse of light 400 may be determined based at least in part on detection of a portion of light from the emitted pulse of light. The portion of the emitted pulse of light (which may be referred to as an optical trigger pulse) may be detected prior to or just after the corresponding emitted pulse of light exits the lidar system 100 (e.g., less than 10 ns after the emitted pulse of light exits the lidar system). The optical trigger pulse may be detected by a separate detector (e.g., a PIN photodiode or an APD) or by the receiver 140. The optical trigger pulse may be produced when a portion of light from an emitted pulse of light is scattered or reflected from a surface located within lidar system 100 (e.g., a surface of a beam splitter or window, or a surface of light source 110, mirror 115, or scanner 120). Some of the scattered or reflected light may be received by a detector 340 of receiver 140, and a pulse-detection circuit 365 coupled to the detector 340 may be used to determine that an optical trigger pulse has been detected. The time at which the optical trigger pulse was detected may be used to determine the emission time of the pulse of light 400.

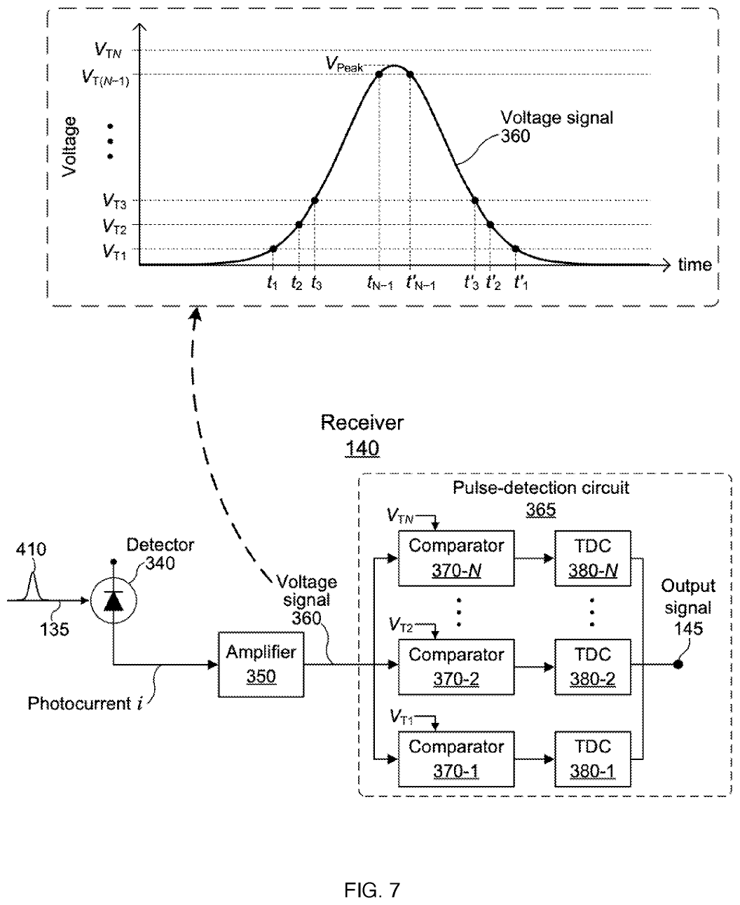

FIG. 7 illustrates an example receiver 140 and an example voltage signal 360 corresponding to a received pulse of light 410. The voltage signal 360 and the received pulse of light 410 corresponding to one another may refer to the voltage signal 360 and the pulse of light 410 having similar rise times, fall times, shapes, durations, or other similar pulse characteristics. For example, the voltage signal 360 may have a rise time, fall time, or duration that is between 1× and 1.5× that of the pulse of light 410. The voltage signal 360 may have a somewhat longer rise time, fall time, or duration due to a limited electrical bandwidth of the detector 340 or the amplifier 350. As another example, the received pulse of light may have a 1-ns rise time and a 4-ns duration, and the corresponding voltage signal 360 may have a 1.5-ns rise time and a 7-ns duration. A light source 110 of a lidar system 100 may emit a pulse of light 400, and a receiver 140 may be configured to detect an input beam 135 that includes a received pulse of light 410 (where the received pulse of light includes a portion of the emitted pulse of light 400 scattered by a remote target 130). In particular embodiments, a receiver 140 of a lidar system 100 may include one or more detectors 340, one or more electronic amplifiers 350, multiple comparators 370, or multiple time-to-digital converters (TDCs) 380. The receiver 140 in FIG. 7 includes a detector 340 configured to receive input light 135 and produce a photocurrent i that corresponds to the received pulse of light 410. The amplifier 350 amplifies the photocurrent i to produce a voltage signal 360 that is sent to the pulse-detection circuit 365. The receiver in FIG. 7 is similar to that of FIG. 6, except in FIG. 7, the pulse-detection circuit 365 includes multiple comparators 370 and multiple TDCs 380.

In FIG. 7, the voltage signal 360 produced by the amplifier 350 is coupled to N comparators (comparators 370-1, 370-2, . . . , 370-N), and each comparator is supplied with a particular threshold voltage (V_{T1}, V_{T2}, . . . , V_{TN}). A pulse-detection circuit 365 may include 1, 2, 5, 10, 50, 100, 500, 1000, or any other suitable number of comparators 370, and each comparator 370 may be supplied with a different threshold voltage. The pulse-detection circuit 365 in FIG. 6 includes one comparator 370, while the pulse-detection circuit 365 in FIG. 7 includes multiple comparators 370. For example, the pulse-detection circuit 365 in FIG. 7 may include N=10 comparators, and the threshold voltages may be set to 10 values between 0 volts and 1 volt (e.g., V_{T1}=0.1 V, V_{T2}=0.2 V, and V_{T10}=1.0 V). Each comparator may produce an electrical-edge signal (e.g., a rising or falling electrical edge) when the voltage signal 360 rises above or falls below a particular threshold voltage. For example, comparator 370-2 may produce a rising edge (at time t₂) when the voltage signal 360 rises above the threshold voltage V_{T2}, and comparator 370-2 may produce a falling edge (at time t′₂) when the voltage signal 360 falls below the threshold voltage V_{T2}.

The pulse-detection circuit 365 in FIG. 7 includes N time-to-digital converters (TDCs 380-1, 380-2, . . . , 380-N), and each comparator 370 is coupled to a TDC 380. Each comparator-TDC pair in FIG. 7 (e.g., comparator 370-1 and TDC 380-1) may be referred to as a threshold detector. A comparator may provide an electrical-edge signal to a corresponding TDC, and the TDC may act as a timer that produces an electrical output signal that represents a time when the edge signal is received from the comparator. For example, when the voltage signal 360 rises above the threshold voltage V_{T1} at time t₁, comparator 370-1 may produce a rising-edge signal that is supplied to the input of TDC 380-1, and the TDC 380-1 may produce a digital time value corresponding to time t₁. Additionally, when the voltage signal 360 subsequently falls below the threshold voltage V_{T1} at time t′₁, the comparator 370-1 may produce a falling-edge signal that is supplied to the input of TDC 380-1, and TDC 380-1 may produce another digital time value corresponding to time t′₁. The digital time values may be referenced to a time when a pulse of light 400 is emitted by a light source 110, and one or more digital time values may correspond to or may be used to determine a round-trip time for the pulse of light to travel from a lidar system 100, to a target 130, and back to the lidar system 100.

In particular embodiments, an output signal 145 of a pulse-detection circuit 365 may include an electrical signal that corresponds to a received pulse of light 410. For example, the output signal 145 in FIG. 7 may be a digital signal that corresponds to the analog voltage signal 360, which in turn corresponds to the photocurrent signal i, which in turn corresponds to the received pulse of light 410. The output signal 145 may include one or more digital time values from each of the TDCs 380 that received one or more edge signals from a comparator 370, and the digital time values may represent the analog voltage signal 360. For example, TDC 380-1 may provide two digital time values (corresponding to times t₁ and t′₁) as part of the output signal 145. Similarly, TDC 380-2 may provide two digital time values (corresponding to times t₂ and t′₂), and TDC 380-3 may provide two digital time values (corresponding to times t₃ and t′₃). The output signal 145 from a pulse-detection circuit 365 may be sent to a controller 150, and a time of arrival for the received pulse of light (which may be referred to as a time of receipt for the received pulse of light) may be determined based at least in part on the time values produced by the TDCs. For example, the time of arrival may be determined from a time associated with a peak (e.g., Vₚₑₐₖ), a temporal center (e.g., a centroid or weighted average), or a rising or falling edge of the voltage signal 360.

The output signal 145 in FIG. 7 may include digital values from each of the TDCs that receive an edge signal from a comparator, and each digital value may represent a time interval between the emission of an optical pulse by a light source 110 and the receipt of an edge signal from a comparator. For example, a light source 110 may emit a pulse of light 400 that is scattered by a target 130, and a receiver 140 may receive a portion of the scattered pulse of light as an input pulse of light 410. When the light source emits the pulse of light, a count value of the TDCs may be reset to zero counts, and a digital value produced by a TDC 380 may represent an amount of time elapsed since the pulse of light was emitted. Alternatively, the TDCs in receiver 140 may accumulate counts continuously over multiple pulse periods (e.g., for 10, 100, 1,000, 10,000, or 100,000 pulse periods), and when a pulse of light is emitted, instead of resetting a TDC count value to zero counts, a TDC count associated with the time when the pulse was emitted may be stored in memory. After the pulse of light is emitted, the TDCs may continue to accumulate counts that correspond to elapsed time without resetting the TDC count value to zero counts. In this case, a digital value produced by a TDC 380 may represent a count value at the time an edge signal is received by the TDC 380. Additionally, an amount of time elapsed since the pulse of light was emitted may be determined by subtracting a count value associated with the emission of the pulse of light from the count value of the edge signal associated with a received pulse of light 410.

In FIG. 7, when TDC 380-1 receives an edge signal from comparator 370-1, the TDC 380-1 may produce a digital signal that represents the time interval between emission of a pulse of light 400 and receipt of the edge signal. For example, the digital signal may include a digital value that corresponds to the number of clock cycles that elapsed between emission of the pulse of light and receipt of the edge signal. Alternatively, if the TDC 380-1 accumulates counts over multiple pulse periods, then the digital signal may include a digital value that corresponds to the TDC count at the time of receipt of the edge signal. The output signal 145 may include digital values corresponding to one or more times when a pulse of light was emitted and one or more times when a TDC received an edge signal. An output signal 145 from a pulse-detection circuit 365 may correspond to a received pulse of light and may include digital values from each of the TDCs that receive an edge signal from a comparator. The output signal 145 may be sent to a controller 150, and the controller may determine a distance D to the target 130 based at least in part on the output signal 145. Additionally or alternatively, the controller 150 may determine an optical characteristic of a received pulse of light 410 based at least in part on the output signal 145 received from the TDCs of a pulse-detection circuit 365. An optical characteristic of a received pulse of light may include a peak optical intensity, a peak optical power, an average optical power, an optical energy, a shape or amplitude, a time of arrival, a temporal center, a round-trip time of flight, a rise time, a fall time, or a temporal duration or width of the received pulse of light.

The example voltage signal 360 illustrated in FIG. 7 corresponds to a received pulse of light 410. The voltage signal 360 may be an analog signal produced by an electronic amplifier 350 and may correspond to a pulse of light 410 detected by the receiver 140 in FIG. 7. The voltage levels on the y-axis correspond to the threshold voltages V_{T1}, V_{T2}, . . . , V_{TN} of the respective comparators 370-1, 370-2, . . . , 370-N. The time values t₁, t₂, t₃, . . . , t_{N-1} correspond to times when the voltage signal 360 exceeds the corresponding threshold voltages, and the time values t′₁, t′₂, t′₃, . . . , t′_{N-1} correspond to times when the voltage signal 360 falls below the corresponding threshold voltages. For example, at time t₁ when the voltage signal 360 exceeds the threshold voltage V_{T1}, comparator 370-1 may produce an edge signal, and TDC 380-1 may output a digital value corresponding to the time t₁. Additionally, the TDC 380-1 may output a digital value corresponding to the time t′₁ when the voltage signal 360 falls below the threshold voltage V_{T1}. Alternatively, the receiver 140 may include an additional TDC (not illustrated in FIG. 7) configured to produce a digital value corresponding to time t′₁ when the voltage signal 360 falls below the threshold voltage V_{T1}. The output signal 145 from pulse-detection circuit 365 may include one or more digital values that correspond to one or more of the time values t₁, t₂, t₃, . . . , t_{N-1} and t′₁, t′₂, t′₃, . . . , t_{N-1}. Additionally, the output signal 145 may also include one or more values corresponding to the threshold voltages associated with the time values. Since the voltage signal 360 in FIG. 7 does not exceed the threshold voltage V_{TN}, the corresponding comparator 370-N may not produce an edge signal. As a result, TDC 380-N may not produce a time value, or TDC 380-N may produce a signal indicating that no edge signal was received.

A round-trip time of flight (e.g., a time for an emitted pulse of light to travel from the lidar system 100 to a target 130 and back to the lidar system 100) may be determined based on a difference between a time of arrival and a time of emission for a pulse of light, and the distance D to the target 130 may be determined based on the round-trip time of flight. A time of arrival for a received pulse of light 410 may correspond to (i) a time associated with a peak of voltage signal 360, (ii) a time associated with a temporal center of voltage signal 360, or (iii) a time associated with a rising edge of voltage signal 360. For example, in FIG. 7 a time associated with the peak voltage (Vₚₑₐₖ) may be determined based on the threshold voltage V_{T(N-1)} (e.g., an average of the times t_{N-1} and t′_{N-1} may correspond to the peak-voltage time). As another example, a curve-fit or interpolation operation may be applied to the values of an output signal 145 to determine a time associated with the peak voltage or rising edge. A curve may be fit to the values of an output signal 145 to produce a curve that approximates the shape of a received optical pulse 410, and a time associated with the peak or rising edge of the curve may correspond to a peak-voltage time or a rising-edge time. As another example, a curve that is fit to the values of an output signal 145 of a pulse-detection circuit 365 may be used to determine a time associated with a temporal center of voltage signal 360 (e.g., the temporal center may be determined by calculating a centroid or weighted average of the curve).

A duration of a received pulse of light 410 may be determined from a duration or width of a corresponding voltage signal 360. For example, the difference between two time values of an output signal 145 may be used to determine a duration of a received pulse of light. In the example of FIG. 7, the duration of the pulse of light corresponding to voltage signal 360 may be determined from the difference (t′₃-t₃), which may correspond to a received pulse of light with a pulse duration of 4 nanoseconds. As another example, a controller 150 may apply a curve-fit or interpolation operation to the values of the output signal 145, and the duration of the pulse of light may be determined based on a width of the curve (e.g., a full width at half maximum of the curve).

In particular embodiments, a temporal correction or offset may be applied to a determined time of emission or time of arrival to account for signal delay within a lidar system 100. For example, there may be a time delay of 2 ns between an electrical trigger signal that initiates emission of a pulse of light and a time when the emitted pulse of light exits the lidar system 100. To account for the 2-ns time delay, a 2-ns offset may be added to an initial time of emission determined by a receiver 140 or a controller of the lidar system 100. For example, a receiver 140 may receive an electrical trigger signal at time t_{TRIG} indicating emission of a pulse of light by light source 110. To compensate for the 2-ns delay between the trigger signal and the pulse of light exiting the lidar system 100, the emission time of the pulse of light may be indicated as (t_{TRIG}+2 ns). Similarly, there may be a 1-ns time delay between a received pulse of light entering the lidar system 100 and a time when electrical edge signals corresponding to the received pulse of light are received by one or more TDCs 380 of a receiver 140. To account for the 1-ns time delay, a 1-ns offset may be subtracted from a determined time of arrival.

In particular embodiments, a controller 150 or a receiver 140 may determine, based on a photocurrent signal i produced by a detector 340, a round-trip time τ for a portion of an emitted optical signal to travel to a target 130 and back to a lidar system 100. Additionally, a controller 150 or a receiver 140 may determine a distance D from the lidar system 100 to the target 130 based on the round-trip time T. For example, a detector 340 may produce a pulse of photocurrent i in response to a received pulse of light 410, and an amplifier 350 may produce a voltage pulse (e.g., voltage signal 360) corresponding to the pulse of photocurrent. Based on the voltage signal 360, a controller 150 or a receiver 140 may determine a time of arrival for the received pulse of light. Additionally, the receiver 140 or controller 150 may determine a time of emission for a pulse of light 400 (e.g., a time at which the pulse of light was emitted by a light source 110), where the received pulse of light 410 includes scattered light from the emitted pulse of light. For example, based on the time of arrival (T_{A}) and the time of emission (T_{E}), the controller 150 or receiver 140 may determine the round-trip time τ (e.g., T=T_{A}−T_{E}), and the distance D may be determined from the expression D=c·T/2.

In particular embodiments, a receiver 140 of a lidar system 100 may include one or more analog-to-digital converters (ADCs). As an example, instead of including multiple comparators and TDCs, a receiver 140 may include an ADC that receives a voltage signal 360 from amplifier 350 and produces a digital representation of the voltage signal 360. Although this disclosure describes or illustrates example receivers 140 that include one or more comparators 370 and one or more TDCs 380, a receiver 140 may additionally or alternatively include one or more ADCs. As an example, in FIG. 7, instead of the N comparators 370 and N TDCs 380, the receiver 140 may include an ADC configured to receive the voltage signal 360 and produce a digital output signal that includes digitized values that correspond to the voltage signal 360. One or more of the approaches for determining an optical characteristic of a received pulse of light as described herein may be implemented using a receiver 140 that includes one or more comparators 370 and TDCs 380 or using a receiver 140 that includes one or more ADCs. For example, an optical characteristic of a received pulse of light may be determined from an output signal 145 provided by multiple TDCs 380 of a pulse-detection circuit 365 (as illustrated in FIG. 7), or an optical characteristic may be determined from an output signal 145 provided by one or more ADCs of a pulse-detection circuit.

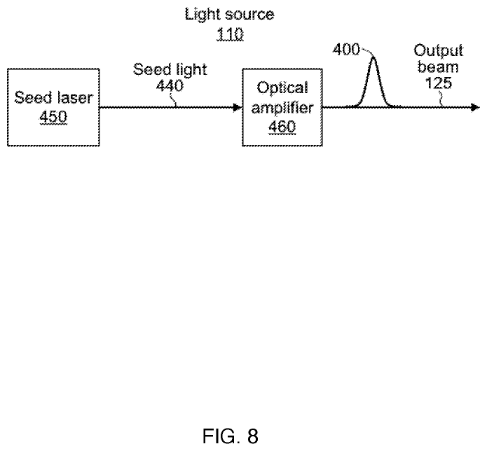

FIG. 8 illustrates an example light source 110 that includes a seed laser diode 450 and a semiconductor optical amplifier (SOA) 460. In particular embodiments, a light source 110 of a lidar system 100 may include (i) a seed laser 450 that produces seed light 440 and LO light (not shown) and (ii) a pulsed optical amplifier 460 that amplifies the seed light 440 to produce emitted pulses of light 400. In various embodiments, lidar system 100 may include multiple instances of light source 110, for example, to emit multiple different output beams at different wavelengths. Each instance of light source 110 can be configured to output a different wavelength. For example, each seed laser 450 can be configured for a different wavelength. In some embodiments, a single instance of light source 110 can be configured to output multiple wavelengths. For example, seed laser 450 can be capable of rapidly switching between different wavelengths. In the example of FIG. 8, the seed laser is a seed laser diode 450 that produces seed light 440 and LO light. The seed laser diode 450 may include a Fabry-Perot laser diode, a quantum well laser, a DBR laser, a DFB laser, a VCSEL, a quantum dot laser diode, or any other suitable type of laser diode. In various embodiments, seed laser diode 450 is a grating-coupled laser diode where current injection modifies the cavity resonance, and a SG-DBR laser is but one example that meets these requirements. In FIG. 8, the pulsed optical amplifier is a semiconductor optical amplifier (SOA) 460 that emits a pulse of light 400 that is part of the output beam 125. An SOA 460 may include a semiconductor optical waveguide that receives the seed light 440 from the seed laser diode 450 and amplifies the seed light 440 as it propagates through the waveguide to produce an emitted pulse of light 400. An SOA 460 may have an optical power gain of 20 decibels (dB), 25 dB, 30 dB, 35 dB, 40 dB, 45 dB, or any other suitable optical power gain. For example, an SOA 460 may have a gain of 40 dB, and a temporal portion of seed light 440 with an energy of 20 pJ may be amplified by the SOA 460 to produce a pulse of light 400 with an energy of approximately 0.2 μJ. A light source 110 that includes a seed laser diode 450 that supplies seed light 440 that is amplified by an SOA 460 may be referred to as a master-oscillator power-amplifier laser (MOPA laser) or a MOPA light source. The seed laser diode 450 may be referred to as a master oscillator, and the SOA 460 may be referred to as a power amplifier. In some embodiments, SOA 460 is a tapered SOA. For example, SOA 460 can include at least a tapered structure and is capable of high output powers for the desired wavelengths.

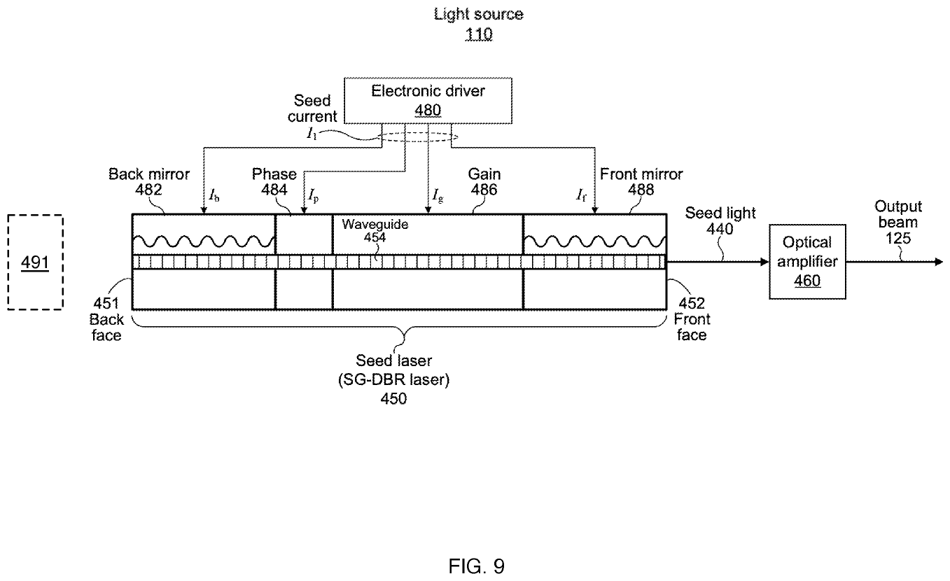

In particular embodiments, a light source 110 may include an electronic driver 480 that (i) supplies electrical current to a seed laser 450 and (ii) supplies electrical current to an SOA 460. In FIG. 8, an electronic driver, such as electronic driver 480 of FIG. 9, supplies seed current h to the seed laser diode 450 to produce the seed light 440 and the LO light. The seed current h supplied to the seed laser diode 450 may be a substantially constant DC electrical current so that the seed light 440 and the LO light each include continuous-wave (CW) light or light having a substantially constant optical power. For example, the seed current I₁ may include a DC current of approximately 1 mA, 10 mA, 100 mA, 200 mA, 500 mA, or any other suitable DC electrical current. Additionally or alternatively, the seed current h may include a pulse of electrical current so that the seed light 440 includes seed pulses of light that are amplified by the SOA 460. The seed laser 450 may be pulsed with a pulse of current having a duration that is long enough so that the wavelength of the seed-laser light emitted by the seed laser 450 (e.g., seed light 440 and LO light) stabilizes or reaches a substantially constant value at some time during the pulse. For example, the duration of the current pulse may be between 50 ns and 2 μs, and the SOA 460 may be configured to amplify a 5-ns temporal portion of the seed light 440 to produce the emitted pulse of light 400. The temporal portion of the seed light 440 that is selected for amplification may be located in time near the middle or end of the electrical current pulse to allow sufficient time for the wavelength of the seed-laser light to stabilize.

In some embodiments, an electronic driver supplies SOA current I₂ to the SOA 460, and the SOA current I₂ provides optical gain to temporal portions of the seed light 440 that propagate through a waveguide of the SOA 460. The SOA current I₂ may include pulses of electrical current, where each pulse of current causes the SOA 460 to amplify one temporal portion of the seed light 440 to produce an emitted pulse of light 400. The SOA current I₂ may have a duration of approximately 0.5 ns, 1 ns, 2 ns, 5 ns, 10 ns, 20 ns, 50 ns, 100 ns, or any other suitable duration. The SOA current I₂ may have a peak amplitude of approximately 1 A, 2 A, 5 A, 10 A, 20 A, 50 A, 100 A, 200 A, 500 A, or any other suitable peak current. For example, the SOA current I₂ supplied to the SOA 460 may include a series of current pulses having a duration of approximately 5-10 ns and a peak current of approximately 100 A. The series of current pulses may result in the emission of a corresponding series of pulses of light 400, and each emitted pulse of light 400 may have a duration that is less than or equal to the duration of the corresponding electrical current pulse. For example, an electronic driver 480 may supply 5-ns duration current pulses to the SOA 460 at a repetition frequency of 700 kHz. This may result in emitted pulses of light 400 that have a duration of approximately 4 ns and a pulse repetition frequency of 700 kHz.

A pulsed optical amplifier may refer to an optical amplifier that is operated in a pulsed mode so that the output beam 125 emitted by the optical amplifier includes pulses of light 400. For example, a pulsed optical amplifier may include an SOA 460 that is operated in a pulsed mode by supplying the SOA 460 with pulses of current. The seed light 440 may include CW light or light having a substantially constant optical power, and each pulse of current supplied to the SOA 460 may amplify a temporal portion of seed light to produce an emitted pulse of light 400. As another example, a pulsed optical amplifier may include an optical amplifier along with an optical modulator. The optical modulator may be an acousto-optic modulator (AOM) or an electro-optic modulator (EOM) operated in a pulsed mode so that the modulator selectively transmits pulses of light. The SOA 460 may also be operated in a pulsed mode in synch with the optical modulator to amplify the temporal portions of the seed light, or the SOA 460 may be supplied with substantially DC current to operate as a CW optical amplifier. The optical modulator may be located between the seed laser diode 450 and the SOA 460, and the optical modulator may be operated in a pulsed mode to transmit temporal portions of the seed light 440 which are then amplified by the SOA 460. Alternatively, the optical modulator may be located after the SOA 460, and the optical modulator may be operated in a pulsed mode to transmit the emitted pulses of light 400.

The seed laser diode 450 illustrated in FIG. 8 includes a front face and a back face. The seed light 440 is emitted from the front face and directed to the input end of the SOA 460. The LO light (not shown) is emitted from the back face and directed to the receiver 140 of the lidar system 100. The seed light 440 or the LO light may be emitted as a free-space beam, and a light source 110 may include one or more lenses (not illustrated in FIG. 8) that (i) collimate the LO light emitted from the back face, (ii) collimate the seed light 440 emitted from the front face, or (iii) focus the seed light 440 into the SOA 460. In some embodiments, light source 110 includes a monitoring module (not shown) for monitoring the current wavelength of seed laser diode 450. For example, the monitoring module can be utilized to determine whether light source 110 has stabilized on the desired wavelength. In some embodiments, the monitoring module is implemented using at least in part an etalon, a detector such as a photodiode, and/or other elements including optical elements.

FIG. 9 illustrates an example light source 110 that includes a semiconductor optical amplifier (SOA) 460. In particular embodiments, an SOA 460 may include an input end, an output end, and an optical waveguide, such as a tapered optical waveguide, extending from the input end to the output end. The input end of the SOA 460 may receive the seed light 440 from the seed laser diode 450. The waveguide (not shown) of the SOA 460 may amplify a temporal portion of the seed light 440 as the temporal portion propagates along the waveguide from the input end to the output end. The amplified temporal portion may be emitted from the output end as an emitted pulse of light (not shown). The emitted pulse of light may be part of the output beam 125, and the light source 110 may include a lens (not shown) configured to collect and collimate emitted pulses of light from the output end to produce a collimated output beam 125. As shown in FIG. 9, the seed laser diode 450 includes back face 451, front face 452, waveguide 454, back mirror 482, phase component 484, gain component 486, and front mirror 488. The seed laser diode 450 in FIG. 9 may have a diode length of approximately 100 μm, 200 μm, 500 μm, 1 mm, or any other suitable length. The SOA 460 may have an amplifier length of approximately 1 mm, 2 mm, 3 mm, 5 mm, 10 mm, 20 mm, or any other suitable length. For example, the seed laser diode 450 may have a diode length of approximately 300 μm, and the SOA 460 may have an amplifier length of approximately 4 mm. In various embodiments, seed laser diode 450 is a grating-coupled laser diode such as a SG-DBR laser. For example, seed laser diode 450 can be a grating-coupled laser diode where current injection modifies the cavity resonance.

In particular embodiments, a waveguide of the SOA 460 may include a semiconductor optical waveguide formed at least in part by the semiconductor material of the SOA 460, and the waveguide may confine light along transverse directions while the light propagates through the SOA 460. In particular embodiments, a waveguide may have a substantially fixed width or a waveguide may have a tapered width. For example, a waveguide may have a substantially fixed width of approximately 5 μm, 10 μm, 20 μm, 50 μm, 100 μm, 200 μm, 500 μm, or any other suitable width. In some embodiments, SOA 460 is a tapered SOA. In FIG. 9, the SOA 460 can include a tapered waveguide with a width that increases from the input end to the output end. For example, the width of the tapered waveguide at the input end may be approximately equal to the width of the waveguide of the seed laser diode 450 (e.g., the input end may have a width of approximately 1 μm, 2 μm, 5 μm, 10 μm, or 50 μm). At the output end of the SOA 460, a tapered waveguide may have a width of approximately 50 μm, 100 μm, 200 μm, 500 μm, 1 mm, or any other suitable width. As another example, the width of the tapered waveguide may increase linearly from a width of approximately 20 μm at the input end to a width of approximately 250 μm at the output end.

In particular embodiments, the input end or the output end of SOA 460 may be a discrete facet formed by a semiconductor air interface. Additionally, the input end or the output end may include a dielectric coating (e.g., an anti-reflection coating to reduce the reflectivity of the input end or the output end). An anti-reflection (AR) coating may have a reflectivity at the seed-laser operating wavelength of less than 5%, 2%, 0.5%, 0.1%, or any other suitable reflectivity value. In FIG. 8, the input end may have an AR coating that reduces the amount of seed light 440 reflected by the input end. In FIG. 8 or FIG. 9, the output end may have an AR coating that reduces the amount of amplified seed light reflected by the output end. An AR coating applied to the input end or the output end may also prevent the SOA 460 from acting as a laser by emitting coherent light when no seed light 440 is present.

In particular embodiments, a light source 110 may include a seed laser diode 450 and an SOA 460 that are integrated together and disposed on or in a single chip or substrate. For example, a seed laser diode 450 and an SOA 460 may each be fabricated separately and then attached to the same substrate (e.g., using epoxy or solder). The substrate may be electrically or thermally conductive, and the substrate may have a coefficient of thermal expansion (CTE) that is approximately equal to the CTE of the seed laser 450 and the SOA 460. As another example, the seed laser diode 450 and the SOA 460 may be fabricated together on the same substrate (e.g., using semiconductor fabrication processes, such as for example, lithography, deposition, and etching). The seed laser diode 450 and the SOA 460 may each include InGaAs or InGaAsP semiconductor structures, and the substrate may include indium phosphide (InP). The InP substrate may be n-doped or p-doped so that it is electrically conductive, and a portion of the InP substrate may act as an anode or cathode for both the seed laser diode 450 and the SOA 460. The substrate may be thermally coupled to (i) a heat sink that dissipates heat produced by the seed laser diode 450 or the SOA 460 or (ii) a temperature-control device (e.g., a thermoelectric cooler) that stabilizes the temperature of the seed laser diode 450 or the SOA 460 to a particular temperature setpoint or to within a particular temperature range. In the example of FIG. 8, the seed laser 450 and the SOA 460 may be separate devices that are not disposed on a single substrate, and the seed light 440 may be a free-space beam. Alternatively, in the example of FIG. 8, the seed laser 450 and the SOA 460 may be separate devices that are disposed together on a single substrate. In the example of FIG. 9, the seed laser 450 and the SOA 460 may be integrated together and disposed on or in a single chip or substrate.

In FIG. 9, rather than having a discrete facet formed by a semiconductor air interface, the front face 452 of the seed laser diode 450 and the input end of the SOA 460 may be coupled together without a semiconductor air interface. For example, the seed laser diode 450 may be directly connected to the SOA 460 so that the seed light 440 is directly coupled from the seed laser diode 450 into the waveguide of the SOA 460. The front face 452 may be butt-coupled or affixed (e.g., using an optically transparent adhesive) to the input end of the SOA 460, or the seed laser diode 450 and the SOA 460 may be fabricated together so that there is no separate front face 452 or input end of the SOA 460 (e.g., the front face 452 and the input end of the SOA 460 may be merged together to form a single interface between the seed laser diode 450 and the SOA 460). Alternatively, the seed laser diode 450 may be coupled to the SOA 460 via a passive optical waveguide that transmits the seed light 440 from the front face 452 of the seed laser diode 450 to the input end of the SOA 460.

In particular embodiments, during a period of time between two successive temporal portions of seed light 440, an SOA 460 may be configured to optically absorb most of the seed light 440 propagating in the SOA 460. The seed light 440 from the seed laser diode 450 may be coupled into the waveguide of the SOA 460. Depending on the amount of SOA current I₂ supplied to the SOA 460, the seed light 440 may be optically amplified or optically absorbed while propagating along the waveguide. If the SOA current I₂ exceeds a threshold gain value (e.g., 100 mA) that overcomes the optical loss of the SOA 460, then the seed light 440 may be optically amplified by stimulated emission of photons. Otherwise, if the SOA current I₂ is less than the threshold gain value, then the seed light 440 may be optically absorbed. The process of optical absorption of the seed light 440 may include photons of the seed light 440 being absorbed by electrons located in the semiconductor structure of the SOA 460.

In particular embodiments, the SOA current I₂ may include pulses of current separated by a period of time that corresponds to the pulse period τ of the light source 110, and each pulse of current may result in the emission of a pulse of light 400. For example, if the SOA current I₂ includes 20-A current pulses with a 10-ns duration, then for each current pulse, a corresponding 10-ns temporal portion of the seed light 440 may be amplified, resulting in the emission of a pulse of light 400. During the time periods τ between successive pulses of current, the SOA current I₂ may be set to approximately zero or to some other value below the threshold gain value, and the seed light 440 present in the SOA 460 during those time periods may be optically absorbed. The optical absorption of the SOA 460 when the SOA current I₂ is zero may be greater than or equal to approximately 10 decibels (dB), 15 dB, 20 dB, 25 dB, or 30 dB. For example, if the optical absorption is greater than or equal to 20 dB, then less than or equal to 1% of the seed light 440 that is coupled into the input end of the waveguide of the SOA 460 may be emitted from the output end of the SOA 460 as unwanted leakage light. Having most of the seed light 440 absorbed in the SOA 460 may prevent unwanted seed light 440 (e.g., seed light 440 located between successive pulses of light 400) from leaking out of the SOA 460 and propagating through the rest of the lidar system 100. Additionally, optically absorbing the unwanted seed light 440 may allow the seed laser 450 to be operated with a substantially constant current I₁ or a substantially constant output power so that the wavelengths of the seed light 440 and LO light are stable and substantially constant.

In particular embodiments, an SOA 460 may include an anode and a cathode that convey SOA current I₂ from an electronic driver 480 to or from the SOA 460. For example, the anode of the SOA 460 may include or may be electrically coupled to a conductive electrode material (e.g., gold) deposited onto the top surface of the SOA 460, and the cathode may include or may be electrically coupled to a substrate located on the opposite side of the SOA 460. Alternatively, the anode of the SOA 460 may include or may be electrically coupled to the substrate of the SOA 460, and the cathode may include or may be electrically coupled to the electrode on the top surface of the SOA 460. An anode may correspond to the p-doped side of a semiconductor p-n junction, and a cathode may correspond to the n-doped side. The anode and cathode may be electrically coupled to the electronic driver 480, and the driver 480 may supply a positive SOA current I₂ that flows from the driver 480 into the anode, through the SOA 460, out of the cathode, and back to the driver 480. When considering the electrical current as being made up of a flow of electrons, then the electrons may be viewed as flowing in the opposite direction (e.g., from the driver 480 into the cathode, through the SOA 460, and out of the anode and back to the driver 480).

In particular embodiments, an electronic driver 480 may electrically couple the SOA anode to the SOA cathode during a period of time between two successive pulses of current. For example, for most or all of the time period τ between two successive pulses of current, the electronic driver 480 may electrically couple the anode and cathode of the SOA 460. Electrically coupling the anode and cathode may include electrically shorting the anode directly to the cathode or coupling the anode and cathode through a particular electrical resistance (e.g., approximately 1Ω, 10Ω, or 100Ω). Alternatively, electrically coupling the anode and the cathode may include applying a reverse-bias voltage (e.g., approximately −1 V, −5 V, or −10 V) to the anode and cathode, where the reverse-bias voltage has a polarity that is opposite the forward-bias polarity associated with the applied pulses of current. By electrically coupling the anode to the cathode, the optical absorption of the SOA may be increased. For example, the optical absorption of the SOA 460 when the anode and cathode are electrically coupled may be increased (compared to the anode and cathode not being electrically coupled) by approximately 3 dB, 5 dB, 10 dB, 15 dB, or 20 dB. The optical absorption of the SOA 460 when the anode and cathode are electrically coupled may be greater than or equal to approximately 20 dB, 25 dB, 30 dB, 35 dB, or 40 dB. For example, the optical absorption of an SOA 460 when the SOA current I₂ is zero and the anode and cathode are not electrically coupled may be 20 dB. When the anode and cathode are electrically shorted together, the optical absorption may increase by 10 dB to 30 dB. If the optical absorption of the SOA 460 is greater than or equal to 30 dB, then less than or equal to 0.1% of the seed light 440 that is coupled into the input end of the waveguide of the SOA 460 may be emitted from the output end of the SOA 460 as unwanted leakage light.

In some embodiments, light source 110 includes optional monitoring module 491 for monitoring the current wavelength of seed laser diode 450. For example, monitoring module 491 can be utilized to determine whether light source 110 has stabilized on the desired wavelength and may allow for more precise tuning of the desired wavelength. In some embodiments, monitoring module 491 is implemented using at least in part an etalon, a detector such as a photodiode, and/or other elements including optical elements. For example, monitoring module 491 can precisely determine wavelength by comparing a monitored transmission through the etalon with respect to the power before the etalon. As another example, monitoring module 491 can precisely determine wavelength by counting the optical fringes of the seed light transmitted through the etalon. In some embodiments, monitoring module 491 can be used to monitor and/or measure frequency-modulated local-oscillator (LO) light produced by light source 110, where the LO light matches the frequency modulation of the emitted seed light 440. For example, monitoring module 491 may be located to the rear of seed laser diode 450 and the LO light may be emitted from the rear or back of seed laser diode 450 towards monitoring module 491. In some embodiments, monitoring module 491 is communicatively connected to a controller unit, such as controller 150 of FIG. 1, for providing monitoring and/or measuring feedback. In some embodiments, monitoring module 491 is communicatively connected to electronic driver 480. In various embodiments, monitoring module 491 is an optional monitoring module and is not required for tuning the wavelength of light source 110.

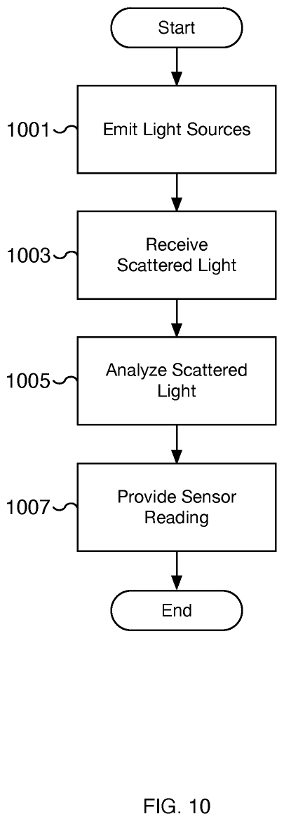

FIG. 10 is a flow chart illustrating an embodiment of a process of a multi-wavelength lidar system for detecting objects. Using the process of FIG. 10, a lidar system can detect objects such as objects downrange from the lidar system. For example, a vehicle equipped with the disclosed lidar system can detect other vehicles, pedestrians, lane markers, and street signs, etc. that are downrange from the vehicle. Depending on the orientation and number of lidar systems installed on the vehicle, different fields of regard can be scanned to determine the corresponding environment surrounding the vehicle. Vehicle safety features as well as autonomous driving features can be implemented using the captured environmental data. In various embodiments, the process of FIG. 10 can be performed by the disclosed lidar systems to detect downrange objects by emitting light pulses of different wavelengths. When an emitted light pulse hits an object, at least a portion of the scattered and/or reflected light can be captured by the lidar system as part of an input beam. In some embodiments, the lidar system performing the process of FIG. 10 is lidar system 100 of FIGS. 1-4 and the light source of the lidar system is light source 110 of FIGS. 1, 3, 8 and/or 9.

At 1001, one or more light sources are emitted. For example, an output light beam is emitted from the lidar system. In some embodiments, the lidar system emits multiple output beams, each potentially offset and/or scanning a different field of regard. In some embodiments, the one or more of the different output beams are at different wavelengths and the different wavelength output beams can be separated in time by an encoding time delay. The encoding time delay used can be stored, for example, as a history of transmitted encoding time delays, and used to match received reflected light to the original transmitted source. In some embodiments, the output beam includes multiple wavelengths that have been multiplexed. In various embodiments, each output beam can reach downrange objects and can be scattered and/or reflected by the downrange object. In some embodiments, each light source can include a configurable laser capable of emitting light pulses of different wavelengths.

At 1003, scattered light is received. For example, light scattered and/or reflected by an object is received at the lidar sensor. The corresponding object can be a downrange object. In various embodiments, the received light has a particular wavelength and corresponds to one of the light sources emitted at 1001. For example, a lidar system emits light pulses of different wavelengths and receives scattered light associated with the different emitted pulses.

At 1005, the received scattered light is analyzed. For example, the received scattered light is directed to a receiver component of the lidar system where sensor data can be captured and analyzed. In some embodiments, the receiver component includes a receive lens for focusing the received scattered light onto a readout integrated circuit (ROIC) of the receiver where one or more detector site locations of the detector plane are located. The detector site locations can be used to detect scatter patterns associated with the received scattered light and the different detector site locations can be offset at least in part to minimize crosstalk between light corresponding to differently aimed output beams. In some embodiments, the received scattered light includes multiple wavelengths that are then split into their different corresponding received pulses by wavelength.

Using detectors positioned at the detector site locations, sensor data can be captured and analyzed for sensor readings. In some embodiments, the analysis is performed at least in part by the readout integrated circuit (ROIC) and/or processor of the receiver and/or a controller of the lidar system. The processing can include determining an output signal corresponding to the detected scatter pattern. In some embodiments, the output signal is a sensor reading that corresponds to a measurement of the detected scattered light, such as an intensity reading or another measured sensor reading. In some embodiments, the received scattered light is associated into groups of received light pulses and the timing between different light pulses in a group is measured. Based on the measured timing, different light pulses are differentiated from one another and used to identify a corresponding transmit pulse to match a received pulse.

At 1007, a sensor reading is provided. For example, one or more sensor readings are provided in response to the analysis of the received scattered light performed at 1005. The sensor reading can be an intensity reading and/or another measurement or measurements. In some embodiments, the sensor reading includes location and/or distance data. For example, sensor readings can correspond to a point cloud based on objects detected in the fields of regard scanned by the lidar system.

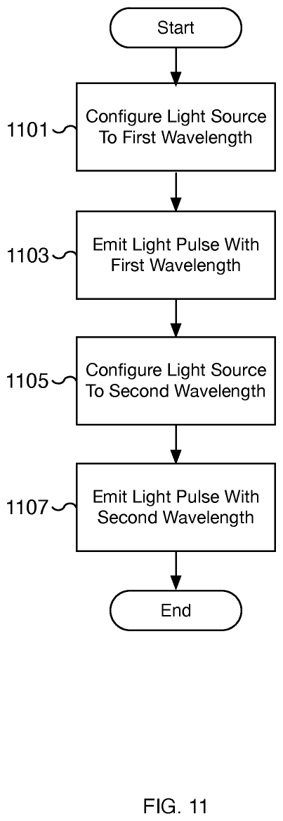

FIG. 11 is a flow chart illustrating an embodiment of a process for emitting multi-wavelength light pulses using a wavelength-tunable laser. Using the process of FIG. 11, a lidar system can utilize at least a light source with a single laser configurable for different wavelengths to emit light pulses of different wavelengths. For example, using the process of FIG. 11, pulses of different wavelengths can be emitted as a group with the pulses within the group intentionally spaced out in time. Although the process of FIG. 11 is described with respect to emitting light pulses of two different wavelengths, the process can be extended to emit light pulses of three or more different wavelengths. Further, the process of FIG. 11 can be repeated to continuously cycle between emitting light pulses of different wavelengths, for example, as part of a scanning process performed by a lidar system. As another example, the wavelengths of the emitted light pulses can randomly or pseudo-randomly accessed as in the use case for arbitrary scanning. In various embodiments, the light source used to emit the different wavelength pulses is a seed laser with an integrated semiconductor optical amplifier (SOA). The laser can be kept in an always on operating mode and a reverse bias can be applied to the SOA, for example, when no light pulse is being emitted, to attenuate the light emitted from the light source. In some embodiments, the process of FIG. 11 is performed by a lidar system at 1001 of FIG. 10. In some embodiments, the lidar system is lidar system 100 of FIGS. 1-4 and the light source is light source 110 of FIGS. 1, 3, 8 and/or 9. In various embodiments, the light source is controlled by a controller such as controller 150 of FIG. 1 during the process of FIG. 11.

At 1101, the light source is configured to the first wavelength. For example, the light source is tuned from its current wavelength configuration to a desired first wavelength. In some embodiments, the wavelength configuration includes using the front mirror section, back mirror section, and/or phase component of a grating-coupled laser diode, such as a sampled-grating distributed Bragg reflector (SG-DBR) laser, to switch the laser from the currently tuned wavelength to the desired first wavelength. In various embodiments, the front and rear mirror sections, phase component, and/or gain component of the laser are controlled by the controller and/or electronic driver component. In some embodiments, the laser is maintained in an always on operating mode to reduce the amount of time required to transition the laser to the desired wavelength when changing wavelengths. For example, in some embodiments, the gain region of the laser is constantly applied with a DC current to maintain the laser in an always on operating mode. Once the laser is tuned to the desired first wavelength, processing proceeds to step 1103. In some embodiments, the wavelength is actively monitored to determine when the laser is tuned to the desired wavelength. In some embodiments, the time required for the wavelength transition period can be approximated by a configured transition time period to allow the wavelength of the laser to stabilize to the desired wavelength.

At 1103, a light pulse is emitted with the first wavelength. For example, once the light source is tuned to the first wavelength, a light pulse is emitted with the first wavelength. In various embodiments, the light source can be emitted by applying a forward bias to the semiconductor optical amplifier (SOA) integrated with the light source's laser. In various embodiments, a reverse bias is applied to attenuate the emitted light as part of generating a light pulse.

At 1105, the light source is configured to the second wavelength. For example, the light source is tuned from the first wavelength configuration to a desired second wavelength. For example, using a process similar to that described with respect to step 1101, the front mirror section, back mirror section, and/or phase component of a sampled-grating distributed Bragg reflector (SG-DBR) laser can be are used to switch the laser from the currently tuned first wavelength to the desired second wavelength. In some embodiments, the laser is maintained in an always on operating mode to reduce the amount of time required to transition the laser to the desired wavelength when changing wavelengths. Once the laser is tuned to the desired second wavelength, processing proceeds to step 1107.

At 1107, a light pulse is emitted with the second wavelength. For example, once the light source is tuned to the second wavelength, a light pulse is emitted with the second wavelength. Using a process similar to that described with respect to step 1103, the light source can be emitted by applying a forward bias to the semiconductor optical amplifier (SOA) integrated with the light source's laser. In various embodiments, a reverse bias is applied to attenuate the emitted light as part of generating a light pulse.

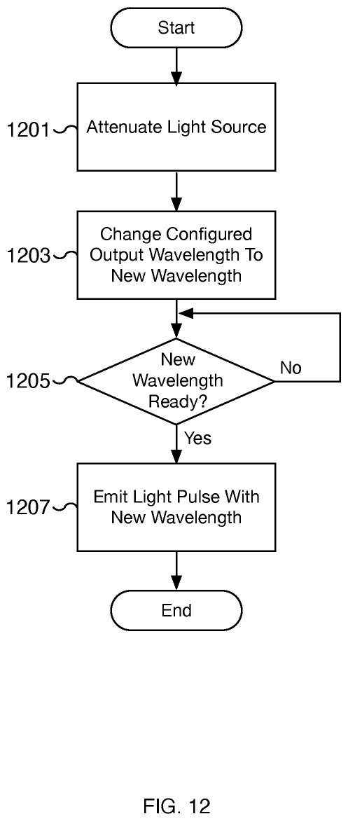

FIG. 12 is a flow chart illustrating an embodiment of a process for emitting a light pulse at a new wavelength using a wavelength-tunable laser. Using the process of FIG. 12, a lidar system can utilize at least a light source with a single laser configurable for different wavelengths to emit light pulses of different wavelengths. In various embodiments, the light source used to emit the different wavelength pulses is a seed laser with an integrated semiconductor optical amplifier (SOA). The laser can be kept in an always on operating mode by constantly applying a DC current to the gain region, allowing the laser to be rapidly switched between different wavelengths. In some embodiments, the process of FIG. 12 is performed by a lidar system for each emitted light pulse at step 1001 of FIG. 10, at steps 1101 and 1103 of FIG. 11, and/or at steps 1105 and 1107 of FIG. 11. In some embodiments, the lidar system is lidar system 100 of FIGS. 1-4 and the light source is light source 110 of FIGS. 1, 3, 8 and/or 9. In various embodiments, the light source is controlled by a controller such as controller 150 of FIG. 1 during the process of FIG. 12.

At 1201, the light source is attenuated. For example, the light source is attenuated to prevent light from being emitted from the light source. In various embodiments, a reverse bias is applied to a semiconductor optical amplifier (SOA) integrated with the light source's laser to attenuate the output light. During this time period, the laser can be maintained in an always on operating mode without light being emitted. In alternative embodiments, the light source is attenuated using a modulator such as a Mach-Zehnder modulator (MZM) or electro-absorption modulator (EAM).

At 1203, the configured output wavelength is changed to a new wavelength. For example, the wavelength of the output light of the light source is changed from its current configured wavelength to a new wavelength. In various embodiments, the control signals to the seed laser are applied to change the seed laser to a new wavelength. For example, the front mirror section, back mirror section, and/or phase component can be manipulated to configure the laser to the new desired wavelength. In various embodiments, the change in wavelength requires a transition time before the laser stabilizes at the new wavelength. During the transition period, no light is emitted from the light source. In various embodiments, the control signals and parameters used to modify the wavelength are stored in a calibrated look-up table. The look-up table can be factory calibrated for a particular configured operating temperature to determine the precise operating parameters such as current and/or voltage to apply to the different sections or components of the laser to achieve a desired wavelength. For example, when changing the output wavelength of the light source, the look-up table is referenced by identifying for a desired wavelength, the correct control signals to apply to the light source, such as the amount of current to apply to the front mirror section, back mirror section, and/or phase component of the seed laser.

In some embodiments, temperature stabilization is performed on the seed laser (e,g., when the wavelength of the light source is changed). For example, the temperature of the seed laser is maintained at a configured operating temperature. In various embodiments, temperature stabilization is performed by applying a constant amount of current to the seed laser. For example, adjustments in the amount of current applied to different portions of the seed laser, such as to the front mirror section and/or back mirror section when changing wavelength, are offset by increasing or decreasing the corresponding amount of current applied to the die of the seed laser, for example, to heater elements associated with the seed laser. By maintaining a constant amount of current to the laser component regardless of the desired wavelength for tuning, the temperature of the seed laser can be maintained at a constant operating temperature.

At 1205, a determination is made whether the laser is tuned to the new wavelength. In the event the laser is ready and tuned to the new wavelength, processing proceeds to 1207. In the event the laser is not ready and not yet tuned to the new wavelength, processing loops back to 1205 to allow the laser sufficient time to transition to the new wavelength. In some embodiments, the current wavelength emitted by the laser is actively monitored, for example, using a monitoring module associated with the laser, to determine whether the new wavelength is ready. In some embodiments, the determination that the new wavelength is ready is based on waiting for a configured transition time period to elapse. The configured transition time period allows the wavelength of the laser to stabilize at the desired wavelength before a pulse is emitted at 1207.

At 1207, a light pulse is emitted with the new wavelength. For example, once the seed laser is tuned to the new wavelength, a light pulse of the new wavelength is emitted. In various embodiments, the light pulse is emitted by applying a forward bias to the semiconductor optical amplifier (SOA) integrated with the light source's laser followed by applying a reverse bias to attenuate the emitted light. In various embodiments, applying a reverse bias to the SOA works to attenuate the emitted light as part of generating a light pulse and allows the laser to continue operating in an always on operating mode. For example, the application of the reverse bias to the SOA results in the falling edge associated with the generated light pulse and prevents further light from being emitted by the light source.

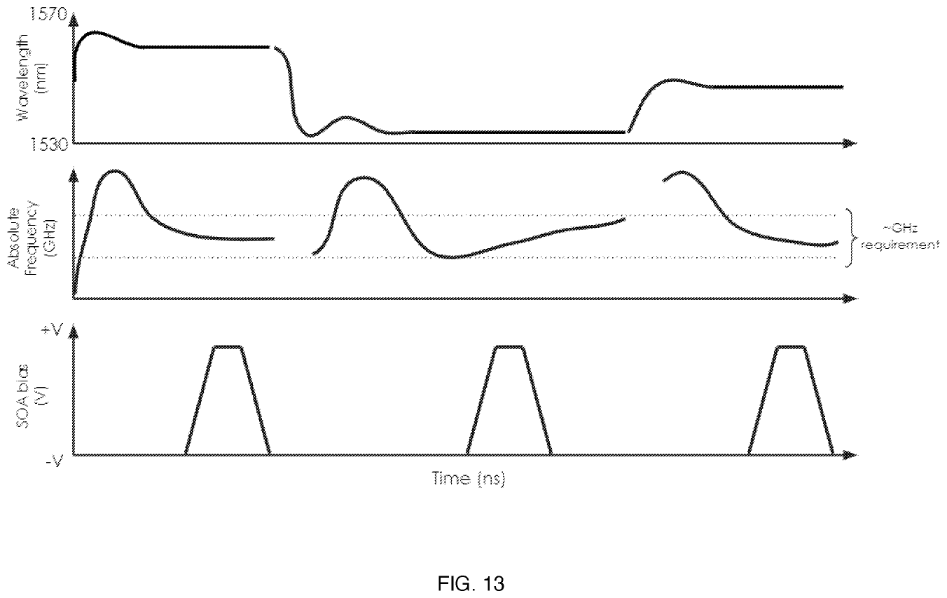

FIG. 13 is a diagram illustrating graphs depicting example operating conditions of a light source when generating light pulses of different wavelengths using a wavelength-tunable laser. In various embodiments, the light source is light source 110 of FIGS. 1, 3, 8 and/or 9 and the included graphs represent example operating conditions of the light source when generating three light pulses of different wavelengths using the processes of FIGS. 10-12. In the diagram of FIG. 13, the X-axis of the three graphs represents time in nanoseconds (ns). The top graph displays the wavelength in nanometers (nm) of the seed-laser of the light source, the middle graph displays the stability or absolute frequency of the desired wavelength in gigahertz (GHz) for the seed-laser, and the bottom graph shows the voltage bias in volts (V) applied to the semiconductor optical amplifier (SOA) integrated with the light source's laser.

In the example shown, the top graph shows that the wavelength of the seed laser operates between 1530 nm and 1570 nm and transitions between three different wavelengths, starting at approximately 1560 nm, transitioning to approximately 1530 nm, and subsequently transitioning to approximately 1550 nm. As the laser transitions between wavelengths, the actual wavelength fluctuates before stabilizing at a new wavelength. The middle graph of FIG. 13 magnifies the transition periods and shows the changing laser's wavelength at a finer resolution using absolute frequency to the desired wavelength. The absolute frequency graph shows the difference in wavelength with a target requirement as upper and lower boundaries corresponding to the dotted horizontal upper and lower bounds. In some embodiments, the target requirement for the desired wavelength is a single-digit GHz target requirement. In various embodiments, once the wavelength settles within the target upper and lower bounds, the wavelength has stabilized sufficiently and the output light can be emitted as a light pulse. The lower graph shows the bias voltage applied to the SOA in order to emit a light pulse at the desired wavelength. As shown in FIG. 13, a reverse bias is applied when no light should be emitted from the light source including when the laser is transitioning to the desired wavelength. Only once the wavelength has stabilized, by applying a forward bias to the SOA for a period of time followed by a reserve bias, a light pulse at the desired wavelength is emitted. As shown in the bottom graph, the SOA bias makes a transition from a reverse bias condition to a forward bias condition and back to a reverse bias condition three times, each time corresponding to an emitted light pulse. The first light pulse corresponds to a light pulse at approximately 1560 nm, the second light pulse corresponds to a light pulse at approximately 1530 nm, and the third light pulse corresponds to a light pulse at approximately 1550 nm. Although the voltage applied to the SOA is shown ramping up and down, in various embodiments, the change in SOA bias can be applied instantaneously or near instantaneously.

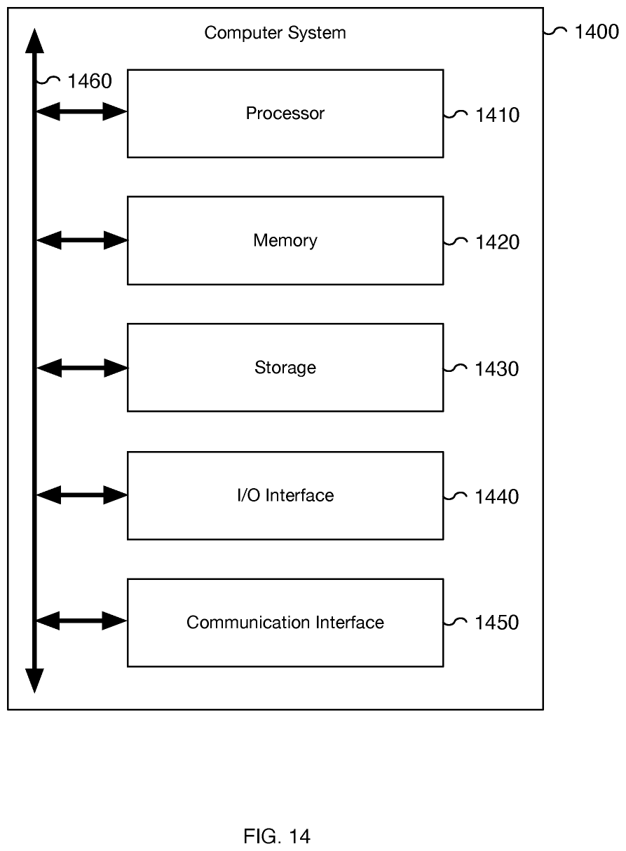

FIG. 14 illustrates an example computer system 1400. In particular embodiments, one or more computer systems 1400 may perform one or more steps of one or more methods described or illustrated herein. In particular embodiments, one or more computer systems 1400 may provide functionality described or illustrated herein. In particular embodiments, software running on one or more computer systems 1400 may perform one or more steps of one or more methods described or illustrated herein or may provide functionality described or illustrated herein. Particular embodiments may include one or more portions of one or more computer systems 1400. In particular embodiments, a computer system may be referred to as a processor, a controller, a computing device, a computing system, a computer, a general-purpose computer, or a data-processing apparatus. Herein, reference to a computer system may encompass one or more computer systems, where appropriate. In some embodiments, computer system 1400 is used to perform one or more of the processes of FIGS. 10-12.

Computer system 1400 may take any suitable physical form. As an example, computer system 1400 may be an embedded computer system, a system-on-chip (SOC), a single-board computer system (SBC), a desktop computer system, a laptop or notebook computer system, a mainframe, a mesh of computer systems, a server, a tablet computer system, or any suitable combination of two or more of these. As another example, all or part of computer system 1400 may be combined with, coupled to, or integrated into a variety of devices, including, but not limited to, a camera, camcorder, personal digital assistant (PDA), mobile telephone, smartphone, electronic reading device (e.g., an e-reader), game console, smart watch, clock, calculator, television monitor, flat-panel display, computer monitor, vehicle display (e.g., odometer display or dashboard display), vehicle navigation system, lidar system, ADAS, autonomous vehicle, autonomous-vehicle driving system, cockpit control, camera view display (e.g., display of a rear-view camera in a vehicle), eyewear, or head-mounted display. Where appropriate, computer system 1400 may include one or more computer systems 1400; be unitary or distributed; span multiple locations; span multiple machines; span multiple data centers; or reside in a cloud, which may include one or more cloud components in one or more networks. Where appropriate, one or more computer systems 1400 may perform without substantial spatial or temporal limitation one or more steps of one or more methods described or illustrated herein. As an example, one or more computer systems 1400 may perform in real time or in batch mode one or more steps of one or more methods described or illustrated herein. One or more computer systems 1400 may perform at different times or at different locations one or more steps of one or more methods described or illustrated herein, where appropriate.

As illustrated in the example of FIG. 14, computer system 1400 may include a processor 1410, memory 1420, storage 1430, an input/output (I/O) interface 1440, a communication interface 1450, or a bus 1460. Computer system 1400 may include any suitable number of any suitable components in any suitable arrangement.

In particular embodiments, processor 1410 may include hardware for executing instructions, such as those making up a computer program. As an example, to execute instructions, processor 1410 may retrieve (or fetch) the instructions from an internal register, an internal cache, memory 1420, or storage 1430; decode and execute them; and then write one or more results to an internal register, an internal cache, memory 1420, or storage 1430. In particular embodiments, processor 1410 may include one or more internal caches for data, instructions, or addresses. Processor 1410 may include any suitable number of any suitable internal caches, where appropriate. As an example, processor 1410 may include one or more instruction caches, one or more data caches, or one or more translation lookaside buffers (TLBs). Instructions in the instruction caches may be copies of instructions in memory 1420 or storage 1430, and the instruction caches may speed up retrieval of those instructions by processor 1410. Data in the data caches may be copies of data in memory 1420 or storage 1430 for instructions executing at processor 1410 to operate on; the results of previous instructions executed at processor 1410 for access by subsequent instructions executing at processor 1410 or for writing to memory 1420 or storage 1430; or other suitable data. The data caches may speed up read or write operations by processor 1410. The TLBs may speed up virtual-address translation for processor 1410. In particular embodiments, processor 1410 may include one or more internal registers for data, instructions, or addresses. Processor 1410 may include any suitable number of any suitable internal registers, where appropriate. Where appropriate, processor 1410 may include one or more arithmetic logic units (ALUs); may be a multi-core processor; or may include one or more processors 1410.

In particular embodiments, memory 1420 may include main memory for storing instructions for processor 1410 to execute or data for processor 1410 to operate on. As an example, computer system 1400 may load instructions from storage 1430 or another source (such as, for example, another computer system 1400) to memory 1420. Processor 1410 may then load the instructions from memory 1420 to an internal register or internal cache. To execute the instructions, processor 1410 may retrieve the instructions from the internal register or internal cache and decode them. During or after execution of the instructions, processor 1410 may write one or more results (which may be intermediate or final results) to the internal register or internal cache. Processor 1410 may then write one or more of those results to memory 1420. One or more memory buses (which may each include an address bus and a data bus) may couple processor 1410 to memory 1420. Bus 1460 may include one or more memory buses. In particular embodiments, one or more memory management units (MMUs) may reside between processor 1410 and memory 1420 and facilitate accesses to memory 1420 requested by processor 1410. In particular embodiments, memory 1420 may include random access memory (RAM). This RAM may be volatile memory, where appropriate. Where appropriate, this RAM may be dynamic RAM (DRAM) or static RAM (SRAM). Memory 1420 may include one or more memories 1420, where appropriate.

In particular embodiments, storage 1430 may include mass storage for data or instructions. As an example, storage 1430 may include a hard disk drive (HDD), a floppy disk drive, flash memory, an optical disc, a magneto-optical disc, magnetic tape, or a Universal Serial Bus (USB) drive or a combination of two or more of these. Storage 1430 may include removable or non-removable (or fixed) media, where appropriate. Storage 1430 may be internal or external to computer system 1400, where appropriate. In particular embodiments, storage 1430 may be non-volatile, solid-state memory. In particular embodiments, storage 1430 may include read-only memory (ROM). Where appropriate, this ROM may be mask ROM (MROM), programmable ROM (PROM), erasable PROM (EPROM), electrically erasable PROM (EEPROM), flash memory, or a combination of two or more of these. Storage 1430 may include one or more storage control units facilitating communication between processor 1410 and storage 1430, where appropriate. Where appropriate, storage 1430 may include one or more storages 1430.

In particular embodiments, I/O interface 1440 may include hardware, software, or both, providing one or more interfaces for communication between computer system 1400 and one or more I/O devices. Computer system 1400 may include one or more of these I/O devices, where appropriate. One or more of these I/O devices may enable communication between a person and computer system 1400. As an example, an I/O device may include a keyboard, keypad, microphone, monitor, mouse, printer, scanner, speaker, camera, stylus, tablet, touch screen, trackball, another suitable I/O device, or any suitable combination of two or more of these. An I/O device may include one or more sensors. Where appropriate, I/O interface 1440 may include one or more device or software drivers enabling processor 1410 to drive one or more of these I/O devices. I/O interface 1440 may include one or more I/O interfaces 1440, where appropriate.

In particular embodiments, communication interface 1450 may include hardware, software, or both providing one or more interfaces for communication (such as, for example, packet-based communication) between computer system 1400 and one or more other computer systems 1400 or one or more networks. As an example, communication interface 1450 may include a network interface controller (NIC) or network adapter for communicating with an Ethernet or other wire-based network or a wireless NIC (WNIC); a wireless adapter for communicating with a wireless network, such as a WI-FI network; or an optical transmitter (e.g., a laser or a light-emitting diode) or an optical receiver (e.g., a photodetector) for communicating using fiber-optic communication or free-space optical communication. Computer system 1400 may communicate with an ad hoc network, a personal area network (PAN), an in-vehicle network (IVN), a local area network (LAN), a wide area network (WAN), a metropolitan area network (MAN), or one or more portions of the Internet or a combination of two or more of these. One or more portions of one or more of these networks may be wired or wireless. As an example, computer system 1400 may communicate with a wireless PAN (WPAN) (such as, for example, a BLUETOOTH WPAN), a WI-FI network, a Worldwide Interoperability for Microwave Access (WiMAX) network, a cellular telephone network (such as, for example, a Global System for Mobile Communications (GSM) network), or other suitable wireless network or a combination of two or more of these. As another example, computer system 1400 may communicate using fiber-optic communication based on 100 Gigabit Ethernet (100 GbE), 10 Gigabit Ethernet (10 GbE), or Synchronous Optical Networking (SONET). Computer system 1400 may include any suitable communication interface 1450 for any of these networks, where appropriate. Communication interface 1450 may include one or more communication interfaces 1450, where appropriate.

In particular embodiments, bus 1460 may include hardware, software, or both coupling components of computer system 1400 to each other. As an example, bus 1460 may include an Accelerated Graphics Port (AGP) or other graphics bus, a controller area network (CAN) bus, an Enhanced Industry Standard Architecture (EISA) bus, a front-side bus (FSB), a HYPERTRANSPORT (HT) interconnect, an Industry Standard Architecture (ISA) bus, an INFINIBAND interconnect, a low-pin-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local bus (VLB), or another suitable bus or a combination of two or more of these. Bus 1460 may include one or more buses 1460, where appropriate.

In particular embodiments, various modules, circuits, systems, methods, or algorithm steps described in connection with the implementations disclosed herein may be implemented as electronic hardware, computer software, or any suitable combination of hardware and software. In particular embodiments, computer software (which may be referred to as software, computer-executable code, computer code, a computer program, computer instructions, or instructions) may be used to perform various functions described or illustrated herein, and computer software may be configured to be executed by or to control the operation of computer system 1400. As an example, computer software may include instructions configured to be executed by processor 1410. In particular embodiments, owing to the interchangeability of hardware and software, the various illustrative logical blocks, modules, circuits, or algorithm steps have been described generally in terms of functionality. Whether such functionality is implemented in hardware, software, or a combination of hardware and software may depend upon the particular application or design constraints imposed on the overall system.

In particular embodiments, a computing device may be used to implement various modules, circuits, systems, methods, or algorithm steps disclosed herein. As an example, all or part of a module, circuit, system, method, or algorithm disclosed herein may be implemented or performed by a general-purpose single- or multi-chip processor, a digital signal processor (DSP), an ASIC, a FPGA, any other suitable programmable-logic device, discrete gate or transistor logic, discrete hardware components, or any suitable combination thereof. A general-purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In particular embodiments, one or more implementations of the subject matter described herein may be implemented as one or more computer programs (e.g., one or more modules of computer-program instructions encoded or stored on a computer-readable non-transitory storage medium). As an example, the steps of a method or algorithm disclosed herein may be implemented in a processor-executable software module which may reside on a computer-readable non-transitory storage medium. In particular embodiments, a computer-readable non-transitory storage medium may include any suitable storage medium that may be used to store or transfer computer software and that may be accessed by a computer system. Herein, a computer-readable non-transitory storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs (e.g., compact discs (CDs), CD-ROM, digital versatile discs (DVDs), blu-ray discs, or laser discs), optical disc drives (ODDs), magneto-optical discs, magneto-optical drives, floppy diskettes, floppy disk drives (FDDs), magnetic tapes, flash memories, solid-state drives (SSDs), RAM, RAM-drives, ROM, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

In particular embodiments, certain features described herein in the context of separate implementations may also be combined and implemented in a single implementation. Conversely, various features that are described in the context of a single implementation may also be implemented in multiple implementations separately or in any suitable sub-combination. Moreover, although features may be described above as acting in certain combinations and even initially claimed as such, one or more features from a claimed combination may in some cases be excised from the combination, and the claimed combination may be directed to a sub-combination or variations of a sub-combination.

While operations may be depicted in the drawings as occurring in a particular order, this should not be understood as requiring that such operations be performed in the particular order shown or in sequential order, or that all operations be performed. Further, the drawings may schematically depict one more example processes or methods in the form of a flow diagram or a sequence diagram. However, other operations that are not depicted may be incorporated in the example processes or methods that are schematically illustrated. For example, one or more additional operations may be performed before, after, simultaneously with, or between any of the illustrated operations. Moreover, one or more operations depicted in a diagram may be repeated, where appropriate. Additionally, operations depicted in a diagram may be performed in any suitable order. Furthermore, although particular components, devices, or systems are described herein as carrying out particular operations, any suitable combination of any suitable components, devices, or systems may be used to carry out any suitable operation or combination of operations. In certain circumstances, multitasking or parallel processing operations may be performed. Moreover, the separation of various system components in the implementations described herein should not be understood as requiring such separation in all implementations, and it should be understood that the described program components and systems may be integrated together in a single software product or packaged into multiple software products.

Various embodiments have been described in connection with the accompanying drawings. However, it should be understood that the figures may not necessarily be drawn to scale. As an example, distances or angles depicted in the figures are illustrative and may not necessarily bear an exact relationship to actual dimensions or layouts of the devices illustrated.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes or illustrates respective embodiments herein as including particular components, elements, functions, operations, or steps, any of these embodiments may include any combination or permutation of any of the components, elements, functions, operations, or steps described or illustrated anywhere herein that a person having ordinary skill in the art would comprehend.

The term “or” as used herein is to be interpreted as an inclusive or meaning any one or any combination, unless expressly indicated otherwise or indicated otherwise by context. Therefore, herein, the expression “A or B” means “A, B, or both A and B.” As another example, herein, “A, B or C” means at least one of the following: A; B; C; A and B; A and C; B and C; A, B and C. An exception to this definition will occur if a combination of elements, devices, steps, or operations is in some way inherently mutually exclusive.

As used herein, words of approximation such as, without limitation, “approximately, “substantially,” or “about” refer to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skill in the art recognize the modified feature as having the required characteristics or capabilities of the unmodified feature. In general, but subject to the preceding discussion, a numerical value herein that is modified by a word of approximation such as “approximately” may vary from the stated value by ±0.5%, ±1%, ±2%, ±3%, ±4%, ±5%, ±10%, ±12%, or ±15%. The term “substantially constant” refers to a value that varies by less than a particular amount over any suitable time interval. For example, a value that is substantially constant may vary by less than or equal to 20%, 10%, 1%, 0.5%, or 0.1% over a time interval of approximately 10⁴ s, 10³ s, 10² s, 10 s, 1 s, 100 ms, 10 ms, 1 ms, 100 μs, 10 μs, or 1 μs. The term “substantially constant” may be applied to any suitable value, such as for example, an optical power, a pulse repetition frequency, an electrical current, a wavelength, an optical or electrical frequency, or an optical or electrical phase.

As used herein, the terms “first,” “second,” “third,” etc. may be used as labels for nouns that they precede, and these terms may not necessarily imply a particular ordering (e.g., a particular spatial, temporal, or logical ordering). As an example, a system may be described as determining a “first result” and a “second result,” and the terms “first” and “second” may not necessarily imply that the first result is determined before the second result.

As used herein, the terms “based on” and “based at least in part on” may be used to describe or present one or more factors that affect a determination, and these terms may not exclude additional factors that may affect a determination. A determination may be based solely on those factors which are presented or may be based at least in part on those factors. The phrase “determine A based on B” indicates that B is a factor that affects the determination of A. In some instances, other factors may also contribute to the determination of A. In other instances, A may be determined based solely on B.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A system, comprising:
a wavelength-tunable light source;
a controller configured to:
cause attenuation of a light being generated by the wavelength-tunable light source during a transition period between a first wavelength to a second wavelength;
cause the wavelength-tunable light source to change a wavelength of the light being generated by the wavelength-tunable light source from the first wavelength to the second wavelength; and
allow a pulse of the light associated with the second wavelength to be emitted during a pulse period after the transition period.

2. The system of claim 1, wherein the wavelength-tunable light source includes a seed laser diode, and wherein the seed laser diode includes a grating-coupled laser diode configured to produce a seed light at a plurality of different wavelengths.

3. The system of claim 2, wherein the wavelength-tunable light source includes an optical amplifier, and wherein the optical amplifier includes a semiconductor optical amplifier (SOA) integrated with the seed laser diode.

4. The system of claim 3, wherein the optical amplifier is configured to amplify or attenuate the seed light produced by the seed laser diode.

5. The system of claim 3, wherein the optical amplifier is configured to receive a reverse bias to attenuate the seed light being produced by the seed laser diode.

6. The system of claim 3, wherein the seed laser diode is configured in an always on operating mode during a time period between a transmission of the pulse of the light associated with the second wavelength and a transmission of a pulse of the light associated with the first wavelength.

7. The system of claim 3, wherein the optical amplifier is configured to receive a reverse bias to attenuate the light being generated by the wavelength-tunable light source during the transition period between the first wavelength to the second wavelength.

8. The system of claim 3, wherein the optical amplifier is configured to produce the pulse of the light associated with the second wavelength by receiving a forward bias to amplify and emit the seed light produced by the seed laser diode followed by a reverse bias to prevent the seed light from being emitted by the wavelength-tunable light source.

9. The system of claim 3, wherein:
the seed laser diode comprises a front mirror, a back mirror, a phase component, and a gain component, wherein the phase and gain components are disposed between the front and back mirrors; and
the wavelength-tunable light source further comprises an electronic driver configured to supply particular combinations of electrical currents to the front mirror, the back mirror, the phase component, and the gain component, wherein a combination of electrical currents causes the seed laser diode to produce the seed light at one of the plurality of different wavelengths.

10. The system of claim 9, wherein values associated with the combination of the electrical currents are stored in a look-up table, and wherein the values are calibrated for a particular operating temperature.

11. The system of claim 1, further comprising:
a scanner configured to scan emitted pulses of light across a field of regard;
a receiver configured to detect a received pulse of light, the received pulse of light comprising a portion of one of the emitted pulses of light scattered by a target located at a distance; and
a processor configured to determine the distance to the target based on a time of arrival of the received pulse of light.

12. The system of claim 11, wherein the controller is further configured to:
allow a pulse of the light associated with the first wavelength to be emitted from the wavelength-tunable light source; and
encode a particular encoding time delay between the pulse of the light associated with the second wavelength and the pulse of the light associated with the first wavelength.

13. A method comprising:
applying a first reverse bias state to an optical amplifier, wherein the optical amplifier is integrated with a seed laser diode, and wherein the seed laser diode is configured to produce a seed light at a plurality of different wavelengths;
sending a constant current to a gain region of the seed laser diode to maintain the seed laser diode in an always on operating mode;
retrieving one or more operating values associated with electrical values based on a desired wavelength, wherein the desired wavelength is one of the plurality of different wavelengths;
applying the retrieved one or more operating values to one or more of a front mirror, a back mirror, or a phase component of the seed laser diode to configure the seed laser diode to operate at the desired wavelength;
waiting for the seed laser diode to stabilize at the desired wavelength;
applying a forward bias state to the optical amplifier, wherein the forward bias state amplifies a light emitted by the seed laser diode at the desired wavelength; and
applying a second reverse bias state to the optical amplifier, wherein the second reverse bias state results in a falling edge of a light pulse associated with the light emitted by the seed laser diode at the desired wavelength.

14. The method of claim 13, wherein retrieving the one or more operating values associated with the electrical values is further based on an operating temperature of the seed laser diode.

15. The method of claim 14, further comprising adjusting a current applied to a die of the seed laser diode to maintain the operating temperature of the seed laser diode and to compensate for applying the retrieved one or more operating values to the one or more of the front mirror, the back mirror, the phase component of the seed laser diode.

16. A system, comprising:
a wavelength-tunable light source;
a controller configured to:
apply a first reverse bias state to an optical amplifier, wherein the optical amplifier is integrated with a grating-coupled laser diode configured to produce a seed light at a plurality of different wavelengths;
retrieve based on a desired wavelength one or more operating values associated with electrical values, wherein the desired wavelength is one of the plurality of different wavelengths;
apply the retrieved one or more operating values to one or more of a front mirror, a back mirror, or a phase component of the grating-coupled laser diode to configure the grating-coupled laser diode to operate at the desired wavelength;
allowing the grating-coupled laser diode to stabilize at the desired wavelength;
apply a forward bias state to the optical amplifier, wherein the forward bias state amplifies a seed light emitted by the grating-coupled laser diode at the desired wavelength; and
apply a second reverse bias state to the optical amplifier, wherein the second reverse bias state results in a falling edge of a light pulse associated with the seed light emitted by the grating-coupled laser diode at the desired wavelength.

17. The system of claim 16, wherein the optical amplifier includes a tapered semiconductor optical amplifier (SOA).

18. The system of claim 16, wherein the one or more operating values associated with the electrical values are stored in a calibrated look-up table.

19. The system of claim 16, wherein allowing the grating-coupled laser diode to stabilize at the desired wavelength includes waiting a configured time period to elapse.

20. The system of claim 16, further comprising a monitoring module, wherein the monitoring module includes at least an etalon and a detector, the monitoring module configured to receive light produced by the grating-coupled laser diode and monitor a current wavelength of the produced light.
